(19) United States
(12) Patent Application Publication
(10) Pub. No.: US 2026/0045785 A1
(43) Pub. Date: Feb. 12, 2026

(54) SIGNAL TRANSMISSION DEVICE, ELECTRONIC DEVICE AND VEHICLE

(71) Applicant: ROHM CO., LTD., Kyoto-shi (JP)

(72) Inventor: Koki MISHIMA, Kyoto-shi (JP)

(21) Appl. No.: 19/290,571

(22) Filed: Aug. 5, 2025

(30) Foreign Application Priority Data
Aug. 7, 2024 (JP) 2024-130687

(51) Int. Cl. H02H 3/20; B60R 16/023; B60R 16/03; H02H 1/00; H03K 17/687

(52) U.S. Cl. CPC H02H 3/20; B60R 16/0231; B60R 16/03; H02H 1/0007; H03K 17/687

(57) ABSTRACT

A signal transmission device includes a transmission-side circuit, a reception-side circuit, an insulating circuit and a protection circuit configured to monitor an SAT voltage for a drive target switch during the on period of the drive target switch. The transmission-side circuit includes a first drive circuit, a second drive circuit and a drive control circuit. When the first drive circuit is enabled and the second drive circuit is disabled, the protection circuit starts monitoring the SAT voltage after a first blanking period has elapsed since a starting point of a transition period of the drive target switch whereas when the first drive circuit is disabled and the second drive circuit is disabled, the protection circuit starts monitoring the SAT voltage after a second blanking period longer than the first blanking period has elapsed since the starting point.

### CROSS REFERENCE TO RELATED APPLICATIONS

The present invention claims priority under 35 U.S.C. § 119 to Japanese Patent Application No. 2024-130687 filed Aug. 7, 2024, the entire contents of which are hereby incorporated by reference.

### TECHNICAL FIELD

The present disclosure relates to a signal transmission device, an electronic device and a vehicle.

### BACKGROUND ART

Conventionally, a signal transmission device which transmits a pulse signal while insulating an area between an input and an output is used in various applications (such as a power supply device and a motor driving device).

### SUMMARY OF INVENTION

A signal transmission device according to an aspect of the present disclosure includes a transmission-side circuit, a reception-side circuit, an insulating circuit and a protection circuit. The transmission-side circuit is configured to output a first internal signal and a second internal signal that are pulse-driven according to a first input signal. The reception-side circuit is configured to output a drive signal according to the first internal signal and the second internal signal so as to drive and control a drive target switch. The insulating circuit is configured to transmit the first internal signal and the second internal signal while insulating an area between the transmission-side circuit and the reception-side circuit. The protection circuit is configured to monitor an SAT voltage for the drive target switch during an on period of the drive target switch. The transmission-side circuit drives at least one of the first internal signal and the second internal signal according to a second input signal different from the first input signal at a specific period different from a period of the first input signal. The reception-side circuit includes: a first drive circuit configured to generate the drive signal based on the first input signal in a state where the reception-side circuit is enabled so as to drive and control the drive target switch; a second drive circuit configured to generate, in the state where the reception-side circuit is enabled, the drive signal to drive the drive target switch at a speed lower than a speed of the first drive circuit so as to drive and control the drive target switch; and a drive control circuit configured to detect that a period of at least one of the first internal signal and the second internal signal is the specific period so as to disable the first drive circuit and enable the second drive circuit. When the first drive circuit is enabled and the second drive circuit is disabled, based on the first input signal and the second input signal, the protection circuit starts monitoring the SAT voltage after a first blanking period has elapsed since a starting point of a transition period from an off state to an on state of the drive target switch or a transition period from the on state to the off state, and when the first drive circuit is disabled and the second drive circuit is disabled, based on the first input signal and the second input signal, the protection circuit starts monitoring the SAT voltage after a second blanking period longer than the first blanking period has elapsed since the starting point.

An electronic device according to an aspect of the present disclosure includes: the signal transmission device of the configuration described above; a control circuit configured to generate the first input signal and the second input signal; and the drive target switch.

A vehicle according to an aspect of the present disclosure includes: the electronic device of the configuration described above.

### BRIEF DESCRIPTION OF DRAWINGS

FIG. 1 is a diagram illustrating the basic configuration of a signal transmission device.

FIG. 2 is a diagram illustrating the basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a diagram showing the basic configuration of an electronic device incorporated in the signal transmission device.

FIG. 11 is a diagram showing the internal configuration of the signal transmission device in the present disclosure.

FIG. 12 is a diagram showing the detailed configuration of logic circuits.

FIG. 13 is a timing chart showing the timing of drive control of a drive target switch using the signal transmission device.

FIG. 14 is a table showing the set state of a first blanking period and a second blanking period.

FIG. 15 is a block diagram showing an example of implementation of the signal transmission device in the present disclosure.

FIG. 16 is a diagram showing a vehicle which includes the electronic device.

### DESCRIPTION OF EMBODIMENTS

### <Signal Transmission Device (Basic Configuration)>

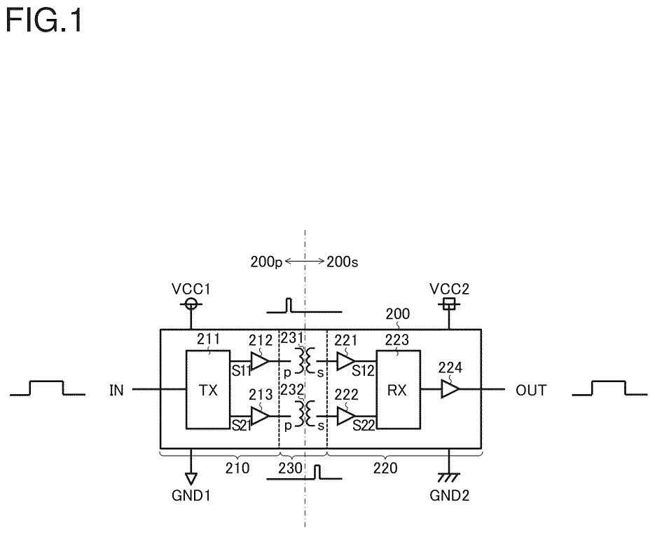

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low—to middle-withstand-voltage process (with a withstand voltage of several volts to several tens of volts). This eliminates the need for a dedicated high-withstand-voltage process (with a withstand voltage of several kilovolts), and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### <Transformer Chip (Basic Structure)>

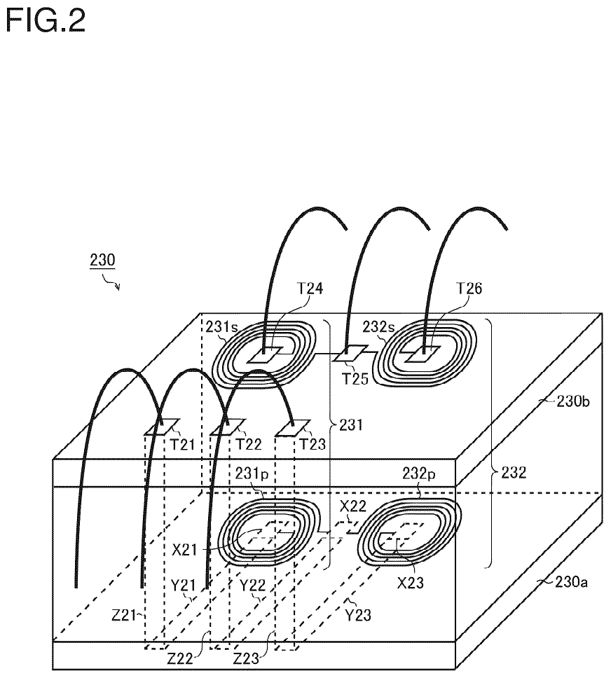

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 232s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230 and is DC-isolated from the controller chip 210 by the transformer chip 230.

### <Transformer Chip (Two-Channel Type)>

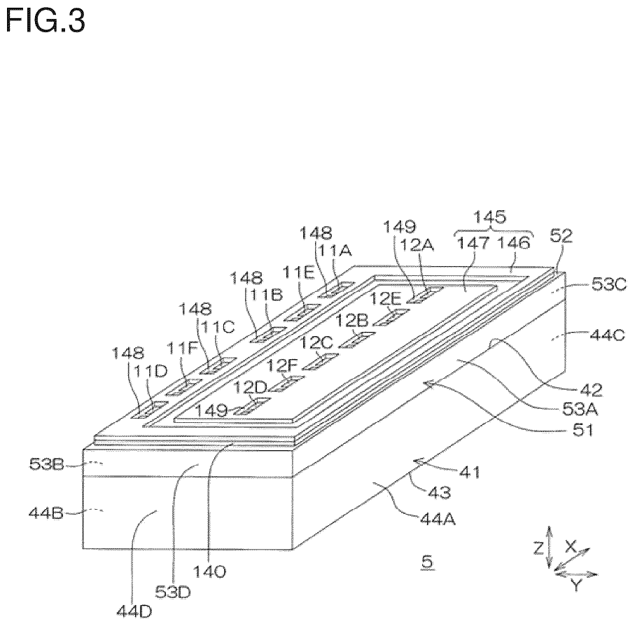

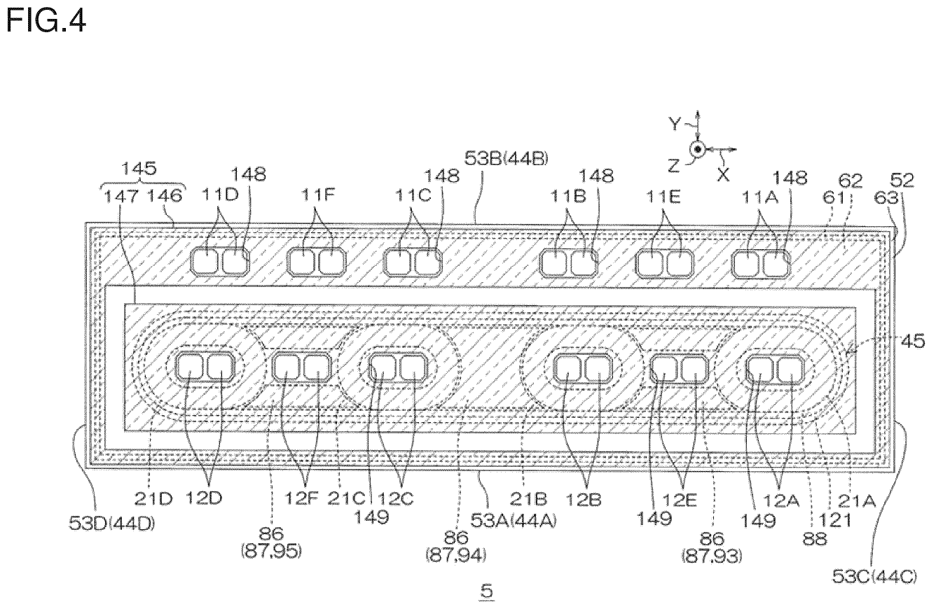

FIG. 3 is a perspective view of a semiconductor device 5 used as a two-channel transformer chip. FIG. 4 is a plan view of the semiconductor device 5 shown in FIG. 3.

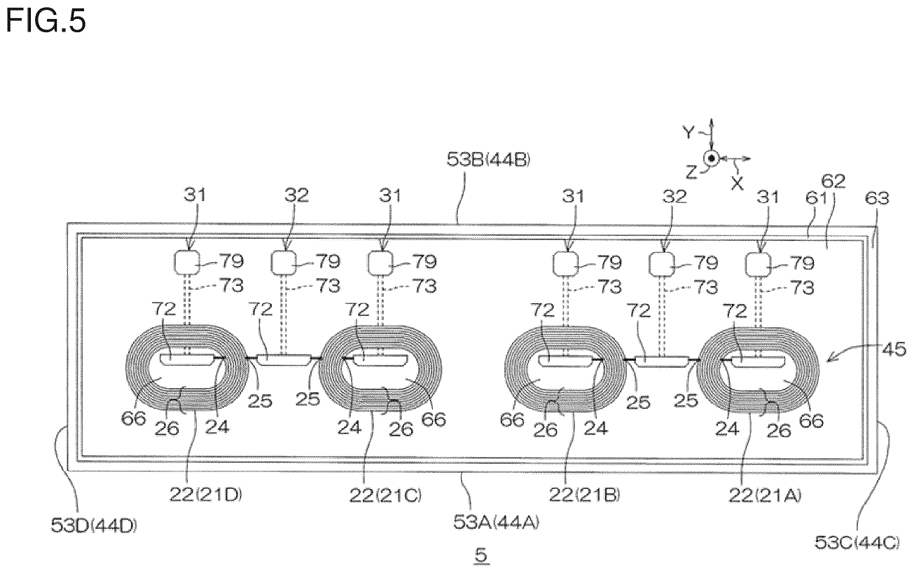

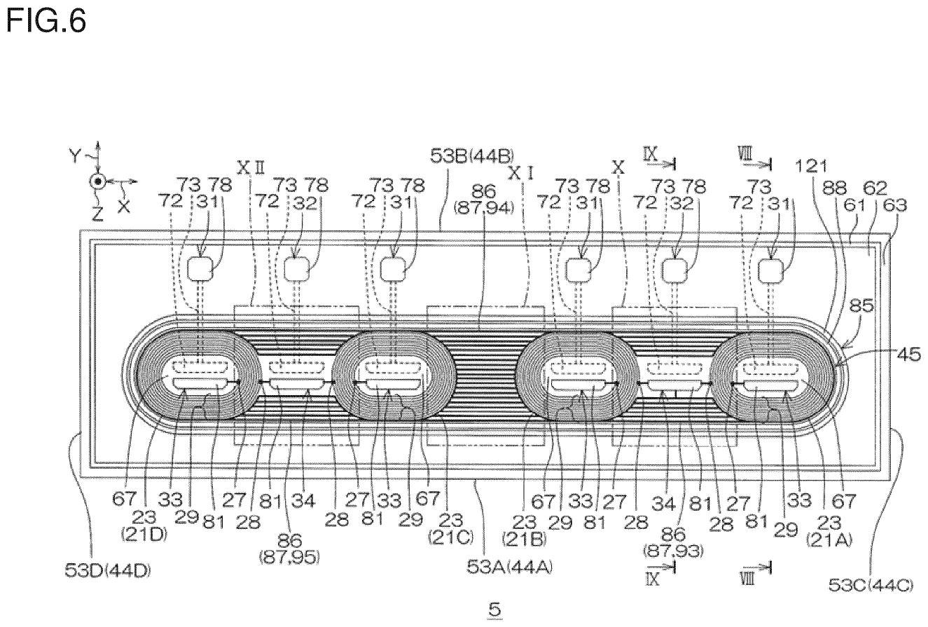

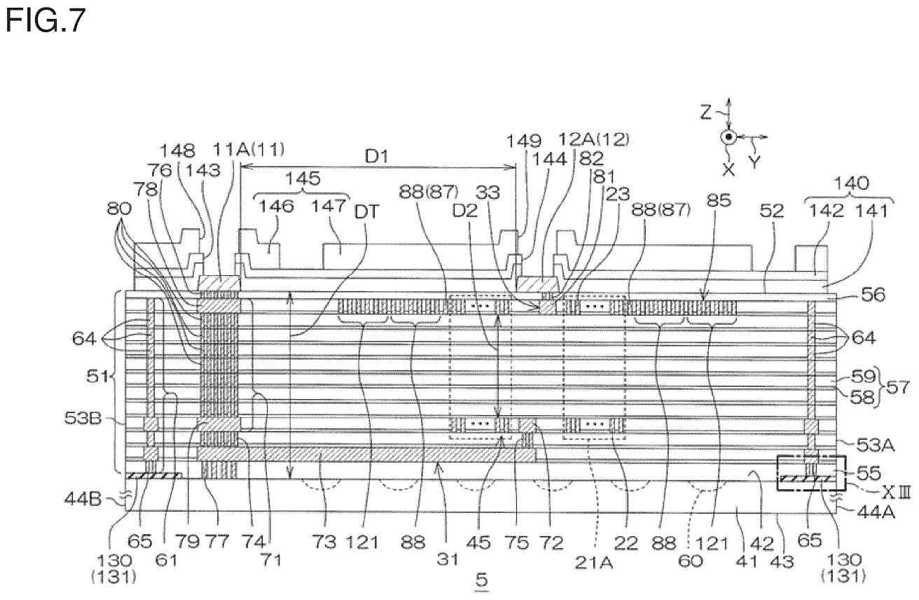

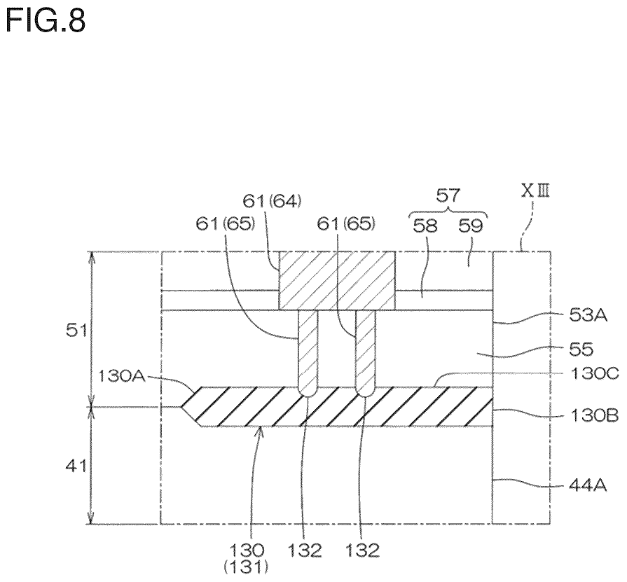

FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIG. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D include a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41 and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58 and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIG. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low- and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low- and high-potential coils 22 and 23 can be disposed at any places. The high-potential coil 23 can face the low-potential coil 22 across one or more interlayer insulation layers 57.

The distance between the low- and high-potential coils 22 and 23 (i.e., the number of interlayer insulation layers 57 stacked together) is adjusted appropriately according to the dielectric strength voltage and electric field strength between the low- and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23 and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22. The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41 and extends in the shape of a stripe in a region between the first and second end parts.

The first connection plug electrode 74 is formed in the interlayer insulation layer 57, in a region between the through wiring 71 and the lead wiring 73, and is electrically connected to the through wiring 71 and to the first end part of the lead wiring 73. The second connection plug electrode 75 is formed in the interlayer insulation layer 57, in a region between the low-potential connection wiring 72 and the lead wiring 73, and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71, and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73 and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low- and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81, and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low- and high-potential terminals 11 and 12 is larger than the distance D2 between the low- and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any value, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high- and low-potential coils 23 and 22, and is independent of the transformers 21A to 21D. That is, the dummy pattern 85 does not function as part of the transformers 21A to 21D. The dummy pattern 85 is formed as a shield conductor layer that shields electric fields between the low- and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of +20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41 and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring, and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low- and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIG. 5 to FIG. 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D as seen in a plan view. In the embodiment, the scaling conductor 61 is formed in a quadrangular ring shape (specifically, a rectangular ring shape) as seen in a plan view. Thus, the sealing conductor 61 defines the device region 62 in a quadrangular shape (specifically, a rectangular shape) as seen in a plan view. Furthermore, the sealing conductor 61 defines the outer region 63 in a quadrangular ring shape (specifically, a rectangular ring shape) surrounding the device region 62 as seen in a plan view.

Specifically, the scaling conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41 and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the scaling conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the scaling conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the scaling plug conductors 64 and the sealing via conductors 65 each include a barrier layer and a body layer.

The plurality of sealing plug conductors 64 are embedded in the plurality of interlayer insulation layers 57 respectively, and are each formed in a quadrangular ring shape (specifically, a rectangular ring shape) surrounding the device region 62 as seen in a plan view. The plurality of sealing plug conductors 64 are stacked together from the bottom insulation layer 55 to the top insulation layer 56 so as to be connected together. The number of layers stacked in the plurality of scaling plug conductors 64 is equal to the number of layers in the plurality of interlayer insulation layers 57. Needless to say, one or a plurality of scaling plug conductors 64 may be formed that penetrates a plurality of interlayer insulation layers 57.

So long as a set of a plurality of sealing plug conductors 64 constitutes one ring-shaped scaling conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of scaling plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41 and are connected to the sealing plug conductors 64. The plurality of scaling via conductors 65 have a plane area smaller than the plane area of the sealing plug conductors 64. In a case where a single scaling via conductor 65 is formed, the single sealing via conductors 65 can have a plane area equal to or larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIG. 7 and FIG. 8, the semiconductor device 5 further includes the separation structure 130 that is interposed between the semiconductor chip 41 and the scaling conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41, and extends in the shape of a stripe along the scaling conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the scaling via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41, and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the scaling via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low- and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146 and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low- and high-potential terminals 11 and 12, it is possible to suppress unnecessary conduction between the high-potential terminal 12 and the sealing conductor 61. Likewise, in a case where a voltage is applied to the second functional device 60 via the low- and high-potential terminals 11 and 12, it is possible to suppress unnecessary conduction between the low-potential terminal 11 and the sealing conductor 61.

The embodiment described above deals with an example where a second functional device 60 is formed. The second functional device 60, however, is not essential, and can be omitted.

The embodiment described above deals with an example where a dummy pattern 85 is formed. The dummy pattern 85 however is not essential and can be omitted.

The embodiment described above deals with an example where the first functional device 45 is of a multichannel type that includes a plurality of transformers 21. It is however also possible to employ a single-channel first functional device 45 that includes a single transformer 21.

### <Transformer Layout >

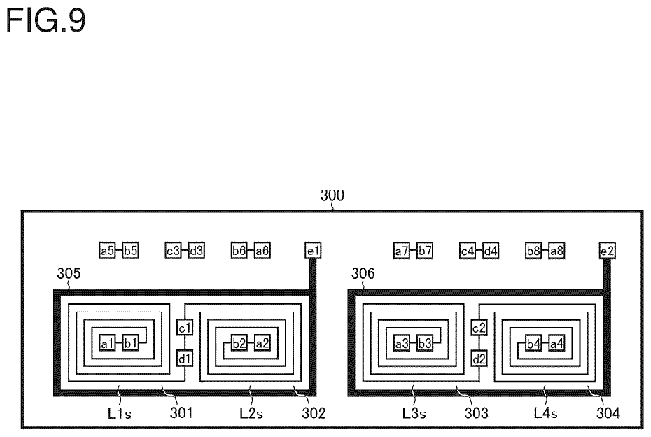

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil LAs.

FIG. 9 does not show any of the primary coils of the first, second, third, and fourth transformers 301, 302, 303, and 304. The primary coils basically have structures similar to those of the secondary coils L1s to L4s respectively and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 304, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate of the transformer chip 300, to obtain a desired withstand voltage between the primary and secondary coils. The first and second guard rings 305 and 306 are, however, not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

<about Electronic Device 400>

The signal transmission device 200 described above can be utilized in an electronic device 400. The electronic device 400 will be described in detail.

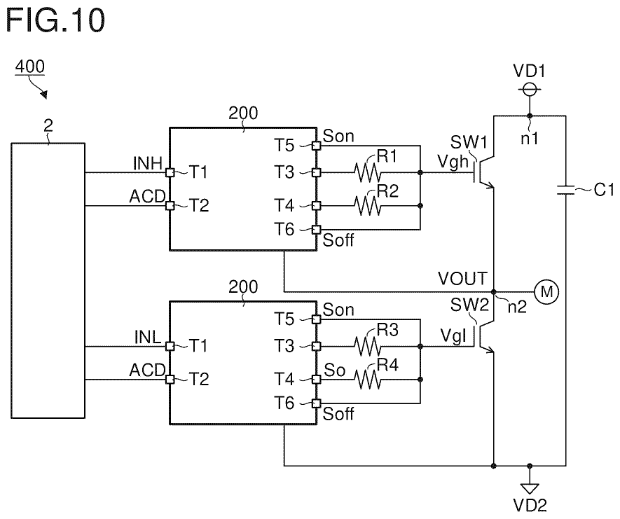

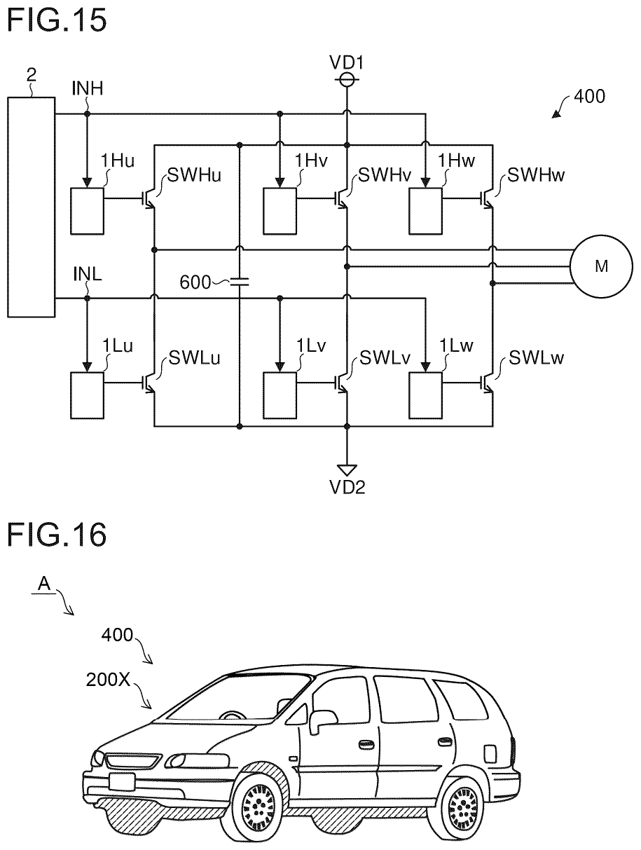

FIG. 10 is a diagram showing the basic configuration of the electronic device 400 incorporated in a signal transmission device 200X. The electronic device 400 of the present configuration example is a type of motor driving device which converts direct-current power supplied from an unillustrated in-vehicle battery into alternating-current power to drive a motor M. The motor M is a three-phase motor which is driven to rotate according to three-phase drive voltages input from three-phase half-bridge output stages (see FIG. 15 which will be described later). FIG. 10 shows only one phase among the three-phase half-bridge output stages.

As shown in FIG. 10, the electronic device 400 of the present configuration example includes an ECU (Electronic Control Unit) 2, a pair of signal transmission devices 200X and a plurality of discrete components (drive target switches SW1 and SW2, resistors R1 to R4 and a capacitor C1).

The first end of the capacitor C1 is connected to the application end of a first motor drive voltage VD1 together with the collector of the drive target switch SW1. The second end of the capacitor C1 is connected to the application end of a second motor drive voltage VD2 together with the emitter of the drive target switch SW2. The capacitor C1 smoothes and stabilizes a direct-current voltage (=voltage between the application ends of the first motor drive voltage VD1 and the second motor drive voltage VD2) which changes according to a change in the power consumption of the motor M.

The ECU 2 is a means for comprehensively performing electrical control on the electronic device 400 and a vehicle A (see FIG. 16 which will be described later) incorporated in the electronic device 400. The ECU 2 switches input signals INH and INL to a high signal level (based on the VCC1) and a low signal level (based on a VEE1) to drive the drive target switches SW1 and SW2. The ECU 2 turns the logic level of a discharge signal ACD (external signal) to a high level (based on the VCC1, first logic level) or a low level (based on the VEE1, second logic level).

The signal transmission device 200X is a semiconductor integrated circuit device. The signal transmission device 200X corresponds to the signal transmission device 200 described previously.

The signal transmission device 200X includes terminals (in the figure, a first external terminal T1, a second external terminal T2, a third external terminal T3, a fourth external terminal T4, a fifth external terminal T5 and a sixth external terminal T6) as means for communicating with the outside.

The input signal INH is input from the ECU 2 to the first external terminal T1. The discharge signal ACD is input from the ECU 2 to the second external terminal T2. The third external terminal T3 is connected to the first end of the resistor R1. The fourth external terminal T4 is connected to the first end of the resistor R2.

The fifth external terminal T5 is connected to the second end of the resistor R1. The sixth external terminal T6 is connected to the second end of the resistor R2. The second end of the resistor R1 is connected to the gate of the drive target switch SW1 together with the second end of the resistor R2.

The drive target switches SW1 and SW2 are IGBTs. The collector of the drive target switch SW1 is connected to the application end of the first motor drive voltage VD1. The emitter of the drive target switch SW1 is connected to the collector of the drive target switch SW2. The emitter of the drive target switch SW2 is connected to the application end of the second motor drive voltage VD2.

The drive target switches SW1 and SW2 configure the half-bridge output stage. An output voltage VOUT is output from a connection node between the drive target switch SW1 and the drive target switch SW2. The application end of the output voltage VOUT is connected to the motor M which is a drive target of the electronic device 400.

For case of description, a connection node between the collector of the drive target switch SW1 and the application end of the first motor drive voltage VD1 is referred to as a node n1. A connection node (=output end of the output voltage VOUT) between the emitter of the drive target switch SW1 and the collector of the drive target switch SW2 is referred to as a node n2.

The signal transmission devices 200X generate drive voltages Vgh and Vg1 corresponding to the input signal INH and the discharge signal ACD to drive and control the drive target switches SW1 and SW2 using the drive voltages Vgh and Vg1.

The drive voltage Vgh is input to the gate of the drive target switch SW1, and thus the drive target switch SW1 is turned on and off according to the drive voltage Vgh. Specifically, when the drive voltage Vgh exceeds the on-threshold voltage of the drive target switch SW1, the drive target switch SW1 is turned on, and furthermore, as the voltage value of the drive voltage Vgh is increased, the on-resistance of the drive target switch SW1 is decreased. On the other hand, when the drive voltage Vgh falls below the on-threshold voltage of the drive target switch SW1, the drive target switch SW1 is turned off, and thus no current flows between the emitter and the collector.

Likewise, the drive voltage Vg1 is input to the gate of the drive target switch SW2, and thus the drive target switch SW2 is turned on and off according to the drive voltage Vg1. Specifically, when the drive voltage Vg1 exceeds the on-threshold voltage of the drive target switch SW2, the drive target switch SW2 is turned on, and furthermore, as the voltage value of the drive voltage Vg1 is increased, the on-resistance of the drive target switch SW2 is decreased. On the other hand, when the drive voltage Vg1 falls below the on-threshold voltage of the drive target switch SW2, the drive target switch SW2 is turned off, and thus no current flows between the emitter and the collector.

### <Soft Turn-Off Function of Signal Transmission Device 200X>

The signal transmission device 200X has a soft turn-on/off function. The soft turning on refers to a turn-on operation in which the slew rate of a rising gate voltage is lower than the slew rate of normal turning on. During the soft turning on, a transition time from an on state to an off state is relatively long. By contrast, the soft turning off refers to a turn-off operation in which the slew rate of a falling gate voltage is lower than the slew rate of normal turning off. During the soft turning off, a transition time from the on state to the off state is relatively long.

When the drive target switches SW1 and SW2 are soft turned on or soft turned off, the signal transmission devices 200X bring the third external terminal T3 and the fourth external terminal T4 into a high impedance state. When the drive target switches SW1 and SW2 are soft turned on, the signal transmission devices 200X output a soft turn-on signal Son from the fifth external terminal T5 in this state. In this way, the drive voltages Vgh and Vg1 correspond to the soft turn-on signal Son.

Likewise, when the drive target switches SW1 and SW2 are soft turned off, the signal transmission devices 200X output a soft turn-off signal Soff from the sixth external terminal T6 in the state described above. In this way, the drive voltages Vgh and Vg1 correspond to the soft turn-off signal Soff. The soft turn-off signal Soff is turned off with a relatively gentle slew rate from a high level (based on the VCC2 which will be described later) to a low level (based on a VEE2 which will be described later). The drive target switch SW1 is gently turned off according to the soft turn-off signal Soff as compared with the normal turning off.

### <Discharge Function of Capacitor Using Soft Turn-Off Function>

The electronic device 400 has the function of drawing out (=discharging) charge from the capacitor C1 at an arbitrary timing such as during a protection operation. When this discharge function is performed, the ECU 2 raises a discharge signal ACD to a high level. In this way, the signal transmission devices 200X perform predetermined operations to perform drive control on the drive target switches SW1 and SW2 and thereby discharge the capacitor C1. When the discharge function is performed, the signal transmission devices 200X perform, for example, the following drive control on the drive target switches SW1 and SW2.

The signal transmission devices 200X drive and control the drive target switches SW1 and SW2 such that two states, that is, a state (first state) where the drive target switch SW1 is soft turned on and the drive target switch SW2 is soft turned off and a state (second state) where the drive target switch SW1 is soft turned off and the drive target switch SW2 is soft turned on are alternately repeated. Then, in the middle of each of the first state and the second state, a timing occurs at which both of the drive target switches SW1 and SW2 are turned on. At this timing, a current flows from the capacitor C1. In this way, the amount of charge in the capacitor C1 is lowered. The amount of discharge (the magnitude of the current value of the current flowing) is decreased as compared with a case where both of the drive target switches SW1 and SW2 are fully turned on, and then the capacitor C1 is discharged. Hence, it is possible to suppress the occurrence of a problem in which the drive target switches SW1 and SW2 are destroyed by an overcurrent.

<about Signal Transmission Device 200X>

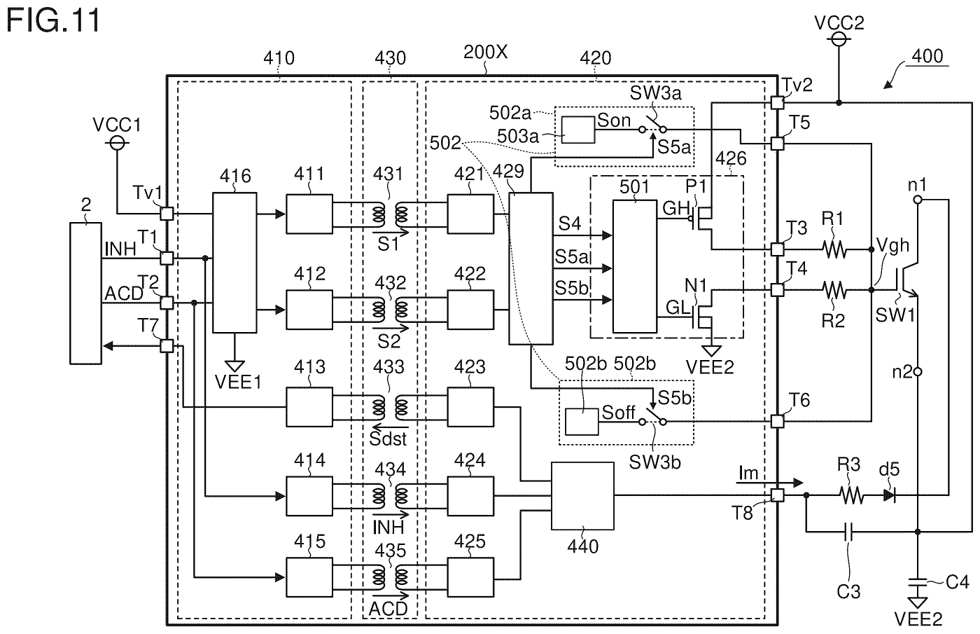

Then, the signal transmission device 200X will be described in detail. FIG. 11 is a diagram showing the internal configuration of the signal transmission device 200X in the present disclosure. As shown in FIG. 11, the signal transmission device 200X is configured to transmit a gate drive signal from a primary circuit system to a secondary circuit system while insulating an area between the primary circuit system (VCC1-VEE1) and the secondary circuit system (VCC2-VEE2).

A primary side power supply terminal Tv1 is a power supply terminal in the primary circuit system (=controller chip 410 which will be described later). The primary circuit system receives the supply of the power supply voltage VCC1 via the primary side power supply terminal Tv1. A secondary side power supply terminal Tv2 is a power supply terminal in the secondary circuit system (=driver chip 420 which will be described later). The secondary circuit system receives the supply of the power supply voltage VCC2 via the secondary side power supply terminal Tv2.

The signal transmission device 200X includes the controller chip 410 (transmission circuit), the driver chip 420 (reception circuit) and a transformer chip 430 (insulating circuit). The signal transmission device 200X seals the controller chip 410, the driver chip 420 and the transformer chip 430 into one package.

The controller chip 410 corresponds to the primary circuit system 200p described previously. The controller chip 410 is a controller chip in which a controller that has the function of generating signals is integrated. The controller chip 410 is driven by receiving the supply of the power supply voltage VCC1. The controller chip 410 generates a first internal signal S1 and a second internal signal S2 based on the input signal INH and the discharge signal ACD.

The controller chip 410 includes a logic circuit 416, a first transmission circuit 411 and a second transmission circuit 412.

The logic circuit 416 receives inputs of the power supply voltage VCC1, the input signal INH and the discharge signal ACD. The logic circuit 416 generates the first internal signal S1 and the second internal signal S2 which are pulse-driven at a predetermined period according to the input signal INH and the discharge signal ACD.

The first transmission circuit 411 and the second transmission circuit 412 receive inputs of the first internal signal S1 and the second internal signal S2 from the logic circuit 416. The first transmission circuit 411 transmits the input first internal signal S1 to the driver chip 420 (specifically, a first reception circuit 421 which will be described later) via the transformer chip 430 (specifically, a first transformer 431 which will be described later). The second transmission circuit 412 transmits the input second internal signal S2 to the driver chip 420 (specifically, a second reception circuit 422 which will be described later) via the transformer chip 430 (specifically, the second transformer 432 which will be described later).

The driver chip 420 corresponds to the secondary circuit system 200s described previously. The driver chip 420 is a driver chip in which a driver for drive control of the drive target switch SW1 is integrated.

The driver chip 420 is driven by receiving the supply of the power supply voltage VCC2. The driver chip 420 generates the drive voltage Vgh according to the first internal signal S1 and the second internal signal S2 which have been received and thereby controls the drive of the drive target switch SW1. The detailed configuration of the driver chip 420 will be described later.

The transformer chip 430 is a transformer chip in which a plurality of transformers (first to fifth transformers 431 to 435 which will be described later) are integrated. The transformer chip 430 transmits the first internal signal S1 and the second internal signal S2 while insulating an area between the controller chip 410 and the driver chip 420 based on a direct current.

The configuration of the driver chip 420 will be described in detail. The driver chip 420 includes the first reception circuit 421, the second reception circuit 422, a logic circuit 429, a first drive circuit 426 and a second drive circuit 502.

The first reception circuit 421 receives an input of the first internal signal S1 from the first transmission circuit 411 via the first transformer 431. The first reception circuit 421 inputs the input first internal signal S1 to the logic circuit 429.

The second reception circuit 422 receives an input of the second internal signal S2 from the second transmission circuit 412 via the second transformer 432. The second reception circuit 422 inputs the input second internal signal S2 to the logic circuit 429.

The logic circuit 429 generates a first drive control signal S4 and second drive control signals S5a and S5b based on the first internal signal S1 and the second internal signal S2 which have been input. The logic circuit 429 inputs the first drive control signal S4 and the second drive control signals S5a and S5b to the first drive circuit 426 (more specifically, a driver circuit 501). The logic circuit 429 also inputs the second drive control signal S5a to a soft turn-on control circuit 502a. The logic circuit 429 also inputs the second drive control signal S5b to a soft turn-off control circuit 502b.

The logic circuit 429 is configured to be able to detect that the first internal signal S1 and the second internal signal S2 are pulse-driven at a specific period (details of which will be described later). Specifically, the logic circuit 429 monitors the drive period of the first internal signal S1 and the second internal signal S2 received by the second reception circuit 422 and detects whether the drive period is the specific period.

The logic circuit 429 outputs the first drive control signal S4 corresponding to the first internal signal S1 and the second internal signal S2 which are driven at a normal period. Here, the logic circuit 429 switches the second drive control signals S5a and S5b low.

When the logic circuit 429 detects that at least one of the first internal signal S1 and the second internal signal S2 are pulse-driven at the specific period, the logic circuit 429 switches the second drive control signals S5a and S5b high. The more detailed configuration of the logic circuit 429 will be described later.

The first drive circuit 426 is switched between a state where the first drive circuit 426 is enabled and a state where the first drive circuit 426 is disabled according to the second drive control signals S5a and S5b. The state where the first drive circuit 426 is enabled refers to a state where voltages at the third external terminal T3 and the fourth external terminal T4 are controlled by the first drive circuit 426, and thus the drive target switch SW1 is driven and controlled. The state where the first drive circuit 426 is disabled refers to a state where the third external terminal T3 and the fourth external terminal T4 are brought into a high impedance state, and thus the drive target switch SW1 is driven and controlled by the soft turn-on control circuit 502a and the soft turn-off control circuit 502b which will be described later.

When both of the second drive control signals S5a and S5b are low, the first drive circuit 426 is enabled. When at least one of the second drive control signals S5a and S5b are high, the first drive circuit 426 is disabled.

The first drive circuit 426 includes the driver circuit 501, a transistor P1 and a transistor N1. The driver circuit 501 outputs drive signals GH and GL based on the first drive control signal S4 and the second drive control signals S5a and S5b which have been input.

The transistor P1 is a P-channel MOSFET (Metal Oxide Semiconductor Field Effect Transistor). The transistor N1 is an N-channel MOSFET. The source of the transistor P1 is connected to the secondary side power supply terminal Tv2. Both the drains of the transistors P1 and N1 are connected to the third external terminal T3. The source of the transistor N1 is connected to the application end of the reference voltage VEE2. The reference voltage VEE2 is lower than the power supply voltage VCC2. The gates of the transistors P1 and N1 are connected to the driver circuit 501.

The drive signal GH is input to the gate of the transistor P1, and thus the turning on and off of the transistor P1 is controlled by the drive signal GH. The drive signal GL is input to the gate of the transistor N1, and thus the turning on and off of the transistor N1 is controlled by the drive signal GL. When the first drive circuit 426 is disabled as described above, the first drive circuit 426 outputs the drive signals GH and GL to turn off both the transistors P1 and N1.

When the transistor P1 is turned on, a high-level (=VCC2 level) voltage is supplied to the third external terminal T3. When the transistor P1 is turned off, the third external terminal T3 is brought into a high impedance state. When the transistor N1 is turned on, a low-level (=VEE2 level) voltage is supplied to the fourth external terminal T4. When the transistor N1 is turned off, the fourth external terminal T4 is brought into a high impedance state.

When the first drive circuit 426 is enabled, the first drive circuit 426 turns on one of the transistors P1 and N1 and turns off the other. In this way, a predetermined voltage (high-level or low-level) is supplied to one of the third external terminal T3 and the fourth external terminal T4, and thus the other is brought into a high impedance state.

The drive voltage Vgh is changed according to the state of the third external terminal T3 and the fourth external terminal T4. For example, when the transistor P1 is turned on, and the transistor N1 is turned off, the power supply voltage VCC2 is supplied to the third external terminal T3, and thus the fourth external terminal T4 is brought into a high impedance state. Here, the drive voltage Vgh is switched high. For example, when the transistor P1 is turned off, and the transistor N1 is turned on, the third external terminal T3 is brought into a high impedance state, and thus the reference voltage VEE2 is supplied to the fourth external terminal T4. Here, the drive voltage Vgh is switched low.

When the first drive circuit 426 is disabled, the first drive circuit 426 turns off the transistors P1 and N1. Hence, the third external terminal T3 and the fourth external terminal T4 are brough into a high impedance state at this time.

In a state where the second drive circuit 502 is enabled, the second drive circuit 502 generates the drive voltage Vgh to turn on and off the drive target switch SW1 at a speed lower than the first drive circuit 426. The meaning of “at a speed lower than the first drive circuit 426” is as follows. The second drive circuit 502 generates the drive voltage Vgh such that the drive target switch SW1 is caused to transition from an on state to an off state (soft turn-off operation) or from the off state to the on state (soft turn-on operation) at a speed slower than the speed at which the drive target switch SW1 is caused by the first drive circuit 426 to transition from the on state to the off state (off operation) or from the off state to the on state (on operation). A specific description will be given below.

The second drive circuit 502 includes the soft turn-on control circuit 502a and the soft turn-off control circuit 502b. The soft turn-on control circuit 502a is switched between a state where the soft turn-on control circuit 502a is enabled and a state where the soft turn-on control circuit 502a is disabled according to the second drive control signal S5a. The soft turn-off control circuit 502b is switched between a state where the soft turn-off control circuit 502b is enabled and a state where the soft turn-off control circuit 502b is disabled according to the second drive control signal S5b.

When the second drive control signal S5a is low, the soft turn-on control circuit 502a is disabled whereas when the second drive control signal S5a is high, the soft turn-on control circuit 502a is enabled.

When soft turn-on control circuit 502a is enabled, the soft turn-on control circuit 502a supplies the soft turn-on signal Son to the fifth external terminal T5. On the other hand, when the soft turn-on control circuit 502a is disabled, the soft turn-on control circuit 502a does not supply the soft turn-on signal Son to the fifth external terminal T5. A specific description will be given below.

The soft turn-on control circuit 502a includes a signal generation circuit 503a and a switch SW3a. The signal generation circuit 503a generates the soft turn-on signal Son. The signal generation circuit 503a is connected to the first end of the switch SW3a. The second end of the switch SW3a is connected to the fifth external terminal T5.

The turning on and off of the switch SW3a is controlled based on the second drive control signal S5a. The above-described state where the soft turn-on control circuit 502a is enabled is a state where the switch SW3a is on. The above-described state where the soft turn-on control circuit 502a is disabled is a state where the switch SW3a is off. A specific description will be given below.

When the second drive control signal S5a is high, the switch SW3a is on. Here, the signal generation circuit 503a is in a conductive state with the fifth external terminal T5, and thus the soft turn-on signal Son is supplied to the fifth external terminal T5. On the other hand, when the second drive control signal S5a is low, the switch SW3a is off, and thus the signal generation circuit 503a is in a non-conductive state with the fifth external terminal T5, with the result that the soft turn-on signal Son is not supplied to the fifth external terminal T5.

When the second drive control signal S5b is low, the soft turn-off control circuit 502b is disabled whereas when the second drive control signal S5b is high, the soft turn-off control circuit 502b is enabled. When the soft turn-off control circuit 502b is enabled, the soft turn-off control circuit 502b supplies the soft turn-off signal Soff to the sixth external terminal T6. On the other hand, when the soft turn-off control circuit 502b is disabled, the soft turn-off control circuit 502b does not supply the soft turn-off signal Soff to the sixth external terminal T6. A specific description will be given below.

The soft turn-off control circuit 502b includes a signal generation circuit 503b and a switch SW3b. The signal generation circuit 503b generates the soft turn-off signal Soff. The signal generation circuit 503b is connected to the first end of the switch SW3b. The second end of the switch SW3b is connected to the sixth external terminal T6.

The turning on and off of the switch SW3b is controlled based on the second drive control signal S5b. The above-described state where the soft turn-off control circuit 502b is enabled is a state where the switch SW3b is on. The above-described state where the soft turn-off control circuit 502b is disabled is a state where the switch SW3b is off. A specific description will be given below.

When the second drive control signal S5b is high, the switch SW3b is on. Here, the signal generation circuit 503b is in a conductive state with the sixth external terminal T6, and thus the soft turn-off signal Soff is supplied to the sixth external terminal T6. On the other hand, when the second drive control signal S5b is low, the switch SW3b is off, and thus the signal generation circuit 503b is in a non-conductive state with the sixth external terminal T6, with the result that the soft turn-off signal Soff is not supplied to the sixth external terminal T6.

When the discharge function described above is performed, its procedure is as follows. An example of control of the drive target switch SW1 when the drive target switch SW2 is soft turned on while the drive target switch SW1 is being soft turned off will first be described.

In this case, the first drive circuit 426 is disabled, and the third external terminal T3 is brought into a high impedance state. Here, the soft turn-on control circuit 502a is enabled, and the soft turn-off control circuit 502b is disabled. In this way, the soft turn-on signal Son is supplied from the fifth external terminal T5 to the gate of the drive target switch SW1. The drive voltage Vgh here corresponds to the soft turn-on signal Son.

Here, in the signal transmission device 200X connected to the drive target switch SW2, the soft turn-on control circuit 502a is disabled, and the soft turn-off control circuit 502b is enabled (not shown). In this way, the soft turn-off signal Soff is supplied to the gate of the drive target switch SW2 (not shown). The drive voltage Vg1 here corresponds to the soft turn-off signal Soff. In this way, a current flows from the capacitor C1, and thus charge is drawn out.

By contrast, an example of control of the drive target switch SW1 when the drive target switch SW2 is soft turned off while the drive target switch SW1 is being soft turned on will be described.

Here, the first drive circuit 426 is disabled, and the third external terminal T3 is brought into a high impedance state. Here, the soft turn-on control circuit 502a is disabled, and the soft turn-off control circuit 502b is enabled. In this way, the soft turn-off signal Soff is supplied from the sixth external terminal T6 to the gate of the drive target switch SW1. The drive voltage Vgh here corresponds to the soft turn-off signal Soff.

Here, in the signal transmission device 200X connected to the drive target switch SW2, the soft turn-on control circuit 502a is enabled, and the soft turn-off control circuit 502b is disabled (not shown). In this way, the soft turn-on signal Son is supplied to the gate of the drive target switch SW2 (not shown). The drive voltage Vg1 here corresponds to the soft turn-on signal Son. In this way, a current flows from the capacitor C1, and thus charge is drawn out.

<Detailed configuration of logic circuits 416 and 429>

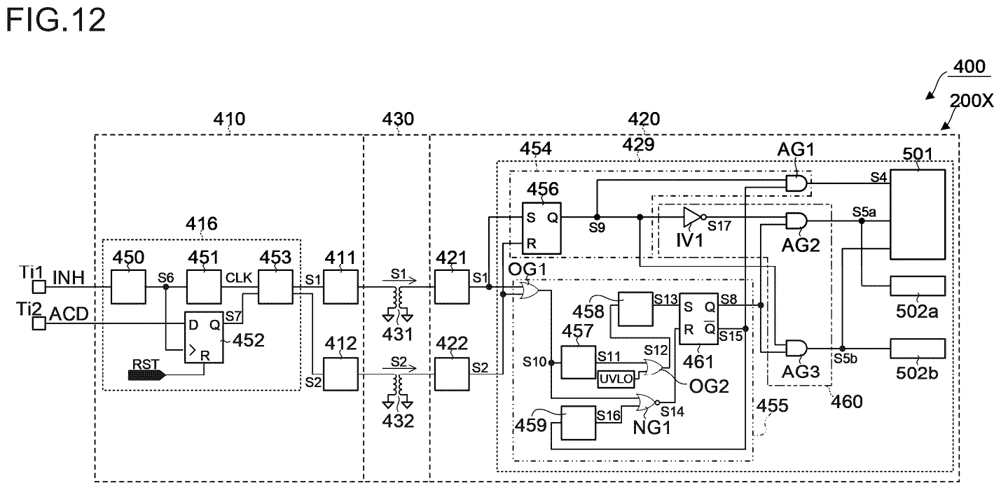

The more detailed configuration of the logic circuits 416 and 429 will then be described. FIG. 12 is a diagram showing the detailed configuration of the logic circuits 416 and 429. As shown in FIG. 12, the logic circuit 416 includes an edge detection circuit 450, a clock circuit 451, a D flip-flop 452 and a pulse generation circuit 453.

The edge detection circuit 450 is connected to the first external terminal T1. The edge detection circuit 450 receives an input of the input signal INH via the first external terminal T1 to generate an edge detection signal S6. When the edge detection circuit 450 detects either a rising edge or a falling edge of the input signal INH, the edge detection circuit 450 generates one pulse in the edge detection signal S6 after a predetermined time has elapsed since the time of the detection (for example, 50 ns after the detection).

The clock circuit 451 receives an input of the edge detection signal S6, generates the clock signal CLK corresponding to the edge detection signal S6 and inputs the clock signal CLK to the pulse generation circuit 453. Specifically, the clock circuit 451 generates the clock signal CLK such that the clock circuit 451 is pulse-driven at a predetermined period after the timing of the pulse edge generated in the edge detection signal S6.

In the D flip-flop 452, the discharge signal ACD is input to an input end (D), the edge detection signal S6 is input to an input end (CK) and a reset signal RST is input to a reset end (R). The D flip-flop 452 outputs a control signal S7 corresponding to the discharge signal ACD and the edge detection signal S6 from the output end (Q) thereof. A specific description will be given below.

When the pulse is generated in the edge detection signal S6, the D flip-flop 452 sets the logic level of the discharge signal ACD to the input end (D) at the timing of the pulse edge (for example, the rising edge) of the edge detection signal S6. In this way, the D flip-flop 452 causes the logic level of the control signal S7 to match the logic level of the input end (D).

In other words, even if the discharge signal ACD is raised from a low level to a high level, the control signal S7 is kept low until the pulse is generated in the edge detection signal S6 (=until the edge detection circuit 450 detects the rising edge or the falling edge of the input signal INH). In other words, when the pulse is generated in the edge detection signal S6 (=when the edge detection circuit 450 detects the rising edge or the falling edge of the input signal INH) in a state where the discharge signal ACD is high, the control signal S7 is raised high.

The reset signal RST is generated by the ECU 2. The ECU 2 raises the reset signal RST from a low level to a high level at an arbitrary timing when the discharge function is not performed. When the reset signal RST is raised high, the logic level which is set to the input end (D) is reset (switched low).

The pulse generation circuit 453 receives inputs of the clock signal CLK and the control signal S7 to generate the first internal signal S1 and the second internal signal S2 corresponding to the clock signal CLK and the control signal S7. The pulse generation circuit 453 pulse-drives one of the first internal signal S1 and the second internal signal S2 according to the clock signal CLK and the control signal S7 at the normal period or the specific period and keeps the other low. A specific description will be given below.

When the input signal INH is high, and the control signal S7 is low (=when the discharge signal ACD is low), the pulse generation circuit 453 pulse-drives the first internal signal S1 at the normal period based on the clock signal CLK, and keeps the second internal signal S2 low.

When the input signal INH is low, and the control signal S7 is low, the pulse generation circuit 453 pulse-drives the second internal signal S2 at the normal period based on the clock signal CLK, and keeps the first internal signal S1 low.

When the control signal S7 is high, the pulse generation circuit 453 pulse-drives one of the first internal signal S1 and the second internal signal S2 at the specific period, and keeps the other low. A specific description will be given below.

When the edge detection circuit 450 detects the rising edge of the input signal INH to raise the control signal S7 high, the input signal INH and the discharge signal ACD are high. Here, the pulse generation circuit 453 pulse-drives the first internal signal S1 at the specific period and keeps the second internal signal S2 low.

By contrast, when the edge detection circuit 450 detects the falling edge of the input signal INH to raise the control signal S7 high, the input signal INH is low, and the discharge signal ACD is high. Here, the pulse generation circuit 453 pulse-drives the second internal signal S2 at the specific period and keeps the first internal signal S1 low.

The normal period is a predetermined period (for example, 100 ns) which is previously set to correspond to the on/off period of the normal (=when the discharge function is not performed) drive target switch SW1. The specific period is a period (for example, 25 ns) which is shorter than the normal period.

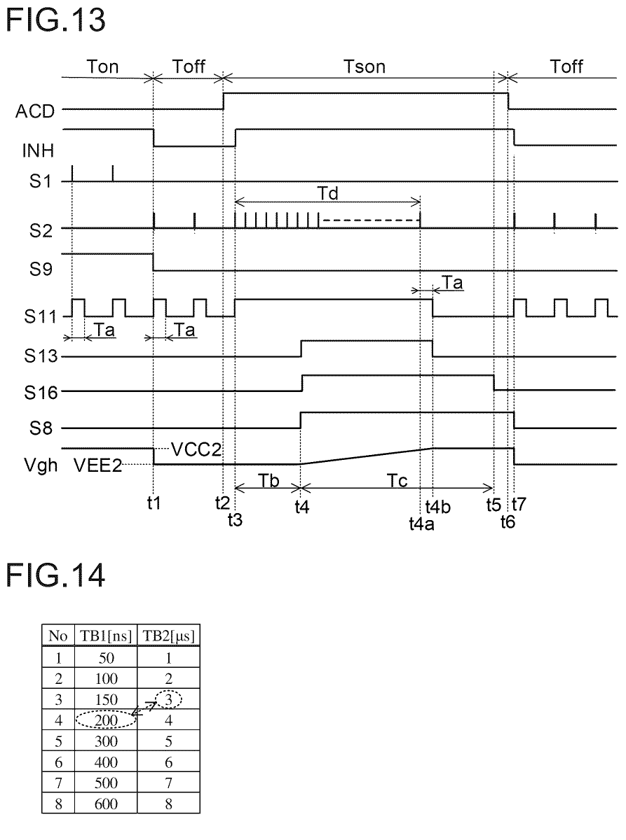

The pulse generation circuit 453 switches both the first internal signal S1 and the second internal signal S2 low after a predetermined pulse stop time Td has elapsed since the start of the pulse-driving of the first internal signal S1 or the second internal signal S2 at the specific period. The pulse stop time Td is set longer than a second time Tb to be described later and shorter than a time obtained by adding the second temperature Tb and a third time Tc. The pulse stop time Td is set shorter than the third time Tc. For example, the pulse stop time Td can be set to 0.5 μs (see FIG. 13 which will be described later).

Then, the detailed configuration of the logic circuit 429 will be described. As shown in FIG. 12, the logic circuit 429 includes a driver control circuit 454, a detection circuit 455 and a discharge control circuit 460.

The driver control circuit 454 generates the first drive control signal S4 according to the first internal signal S1 and the second internal signal S2.

The detection circuit 455 is configured to be able to detect whether one of the first internal signal S1 and the second internal signal S2 is pulse-driven at the specific period by monitoring the first internal signal S1 and the second internal signal S2. The detection circuit 455 generates a detection signal S8 corresponding to the result of the detection.

The discharge control circuit 460 generates the second drive control signal S5a and the second drive control signal S5b corresponding to the first internal signal S1, the second internal signal S2 and the detection signal S8. The detailed configurations of the driver control circuit 454, the detection circuit 455 and the discharge control circuit 460 are as follows.

The driver control circuit 454 includes an RS flip-flop 456 and an AND gate AG1.

In the RS flip-flop 456, the first internal signal S1 is input from the first reception circuit 421 to a set input end(S). In the RS flip-flop 456, the second internal signal S2 is input from the second reception circuit 422 to a reset input end (R). The RS flip-flop 456 outputs a control signal S9 corresponding to the first internal signal S1 and the second internal signal S2 from the output end (Q) thereof.

In the AND gate AG1, the control signal S9 is input to a first input end, and an inverted signal S15 which will be described later is input to a second input end. The AND gate AG1 outputs the first drive control signal S4 corresponding to the control signal S9 and the inverted signal S15.

The detection circuit 455 includes OR gates OG1 and OG2, a NOR gate NG1, a first timer circuit 457, a second timer circuit 458, a third timer circuit 459 (mask circuit) and an RS flip-flop 461.

In the OR gate OG1, the first internal signal S1 is input from the first reception circuit 421 to a first input end. In the OR gate OG1, the second internal signal S2 is input from the second reception circuit 422 to a second input end. The OR gate OG1 outputs a monitoring signal S10 corresponding to the first internal signal S1 and the second internal signal S2 from the output end thereof. A specific description will be given below.

When at least one of the first internal signal S1 and the second internal signal S2 are high, the OR gate OG1 switches the monitoring signal S10 high. When both of the first internal signal S1 and the second internal signal S2 are low, the OR gate OG1 switches the monitoring signal S10 low.

The first timer circuit 457 receives an input of the monitoring signal S10 to output a first timer signal S11 corresponding to the monitoring signal S10. Specifically, the first timer circuit 457 raises the logic level of the first timer signal S11 from a low level to a high level in synchronization with the rising edge of the monitoring signal S10. When a predetermined first time Ta (see FIG. 13 which will be described later) has elapsed after the timing of the rising edge of the first timer signal S11, the first timer circuit 457 drops the logic level of the first timer signal S11 from a high level to a low level.

The first time Ta is set shorter than the normal period and longer than the specific period. For example, when the normal period is set to 100 ns, and the specific period is set to 25 ns, the first time Ta can be set greater than 25 ns and less than 100 ns (for example, 40 ns).

In the OR gate OG2, the first timer signal S11 is input to a first input end. In the OR gate OG2, a UVLO signal which is output by a constant voltage malfunction prevention circuit UVLO is input to a second input end. The OR gate OG2 outputs a control signal S12 corresponding to the UVLO signal and the first timer signal S11 from the output end thereof. A specific description will be given below.

When the power supply voltage falls below a predetermined lower limit voltage, the constant voltage malfunction prevention circuit UVLO brings the function of the detection circuit 455 into a standby state (=temporary stop state) to prevent the malfunction of the detection circuit 455. As long as the supply voltage VCC2 does not fall below the lower limit voltage, the constant voltage malfunction prevention circuit UVLO basically outputs a low-level output signal. In other words, as long as the supply voltage VCC2 does not fall below the lower limit voltage, the OR gate OG2 outputs the control signal S12 which has the logic level equivalent to the first timer signal S11.

The second timer circuit 458 receives an input of the control signal S12 to output a second timer signal S13 corresponding to the control signal S12. A specific description will be given below.

The second timer circuit 458 is configured to be able to detect whether the duration of the high level of the control signal S12 (=time after a starting time when the first timer signal S11 is raised high until the first timer signal S11 is subsequently dropped low) exceeds a predetermined second time Tb (first period). The second timer circuit 458 outputs the second timer signal S13 according to the result of the detection.

Specifically, the third timer circuit 459 keeps the logic level of the second timer signal S13 low until the duration of the high level of the control signal S12 reaches the second time Tb. On the other hand, when the duration of the high level of the control signal S12 reaches the second time Tb, the second timer circuit 458 raises the logic level of the second timer signal S13 high and keeps the logic level of the second timer signal S13 high until the control signal S12 is dropped low. The second time Tb is set longer than the first time Ta (for example, set to 200 ns).

In the RS flip-flop 461, the second timer signal S13 is input to a set input end(S). In the RS flip-flop 461, a control signal S14 which will be described later is input to a reset input end (R). The RS flip-flop 461 outputs the detection signal S8 from the output end (Q) thereof according to the second timer signal S13 and the control signal S14, and outputs the inverted signal S15 from the inverted output end (-Q) thereof. The inverted signal S15 is a signal the logic level of which is inverted from the detection signal S8.

The third timer circuit 459 receives an input of the inverted signal S15 to output a third timer signal S16 corresponding to the inverted signal S15. A specific description will be given below.

The third timer circuit 459 receives an input of the high-level inverted signal S15 to switch the third timer signal S16 low. The third timer circuit 459 keeps the third timer signal S16 high until the predetermined third time Tc (second period) has elapsed after dropping of the inverted signal S15 low. When the third time Te has elapsed, the third timer circuit 459 drops the third timer signal S16 low again.

In the NOR gate NG1, the monitoring signal S10 is input to a first input end, and the third timer signal S16 is input to a second input end. The NOR gate NG1 outputs the control signal S14 corresponding to the monitoring signal S10 and the third timer signal S16. A specific description will be given below.

While the third timer signal S16 is being kept low, the NOR gate NG1 pulse-drives the control signal S14 such that the logic level is inverted from the pulse of the monitoring signal S10. In other words, in the meantime, the control signal S14 is pulse-driven at the specific period. While the third timer signal S16 is being kept high, the NOR gate NG1 keeps the control signal S14 low regardless of the logic level of the monitoring signal S10.

Hence, while the third timer circuit 459 is keeping the third timer signal S16 low, in the RS flip-flop 461, the low-level second timer signal S13 is input to a set input end(S), and the control signal S14 which is pulse-driven at the specific period is input to a reset input end (R). In other words, in the meantime, in the RS flip-flop 461, the holding and resetting of the logic level of the output end (Q) thereof is repeated, and thus the detection signal S8 is kept low.

On the other hand, while the third timer circuit 459 is keeping the third timer signal S16 high, in the RS flip-flop 461, the high-level second timer signal S13 is input to the set input end(S), and the control signal S14 which is kept low is input to the reset input end (R). In other words, in the meantime, in the RS flip-flop 461, the holding and resetting of the logic level of the output end (Q) thereof is repeated, and thus the detection signal S8 is kept high. As described above, the third timer circuit 459 keeps the third timer signal S16 high, and thus the logic level of the detection signal S8 is prevented from being changed even if the monitoring signal S10 is pulse-driven.

In other words, the third timer circuit 459 masks the monitoring signal S10 in a state where the detection signal S8 is high (=state where the detection circuit 455 detects that the pulse period of the first internal signal S1 or the second internal signal S2 is the specific period). In this way, In the state where the detection signal S8 is high, a change in the logic level of the first internal signal S1 or the second internal signal S2 is prevented from being transmitted to the AND gate AG1 and AND gates AG2 and AG3 which will be described later. Hence, in the state where the detection signal S8 is high, the dropping of both the second drive control signals S5a and S5b low is suppressed.

The discharge control circuit 460 includes an inverter IVI and the AND gates AG2 and AG3. The inverter IVI receives an input of the control signal S9 to output a control signal S17 the logic level of which is inverted from the control signal S9.

In the AND gate AG2, the control signal S17 is input to a first input end, and the detection signal S8 is input to a second input end. The AND gate AG2 outputs the second drive control signal S5a corresponding to the control signal S17 and the detection signal S8.

In the AND gate AG3, the control signal S9 is input to a first input end, and the detection signal S8 is input to a second input end. The AND gate AG3 outputs the second drive control signal S5b corresponding to the detection signal S8 and the control signal S9.

### <Internal Control During Soft Turning On>

Internal control when the signal transmission device 200X soft turns on the drive target switch SW1 will then be described. In the following description, as an example of the control during the soft turning on, a case where the edge detection circuit 450 detects the rising edge of the input signal INH to drop the control signal S7 low (=case where the first internal signal S1 is pulse-driven at the specific period, and thus the second internal signal S2 is kept low) will be described.

FIG. 13 is a timing chart showing the timing of drive control of the drive target switch SW1 using the signal transmission device X. FIG. 13 shows, sequentially from above, the discharge signal ACD, the input signal INH, the first internal signal S1, the second internal signal S2, the first timer signal S11, the second timer signal S13, the third timer signal S16, the detection signal S8, the control signal S9 and the drive voltage Vgh.

In FIG. 13, during a period from time t1 to time t2, the turning on and off of the drive target switch SW1 is normally controlled. More specifically, a period before time t1 is an on period Ton of the drive target switch SW1. The period from time t1 to time t2 is an off-period Toff of the drive target switch SW1. During a period from time t2 to time t6, the discharge function is performed, and the period is a soft turn-on period Tson of the drive target switch SW1 (=period during which the drive target switch SW1 is soft turned on). A period after time t7 is a normal off period Toff after the completion of the discharge function.

The ECU 2 keeps the discharge signal ACD low until time t2 arrives after an unillustrated predetermined timing. The ECU 2 keeps the input signal INH high until time t1 arrives after an unillustrated predetermined timing.

Before time t1, the logic circuit 416 receives an input of the low-level input signal INH to keep the second internal signal S2 low while pulse-driving the first internal signal S1 at the normal period (in the figure, 100 ns).

Before time t1, in the RS flip-flop 456, the first internal signal S1 which is pulse-driven at the normal period is input to a set terminal(S), and the second internal signal S2 which is kept low is input to a reset terminal (R). Hence, the RS flip-flop 456 keeps the control signal S9 high until time t1 arrives.

Before time t1, in the OR gate OG1, the first internal signal S1 which is pulse-driven at the normal period is input to the first input end, and the second internal signal S2 which is kept low is input to the second input end. Hence, the OR gate OG1 pulse-drives the monitoring signal S10 in synchronization with the pulse-driving of the first internal signal S1 until time t1 arrives (not shown).

Before time t1, the first timer circuit 457 raises the first timer signal S11 from a low level to a high level in accordance with the timing of the pulse of the monitoring signal S10 (=timing of the pulse of the first internal signal S1). Then, the first timer signal S11 is kept high until the first time Ta (in the figure, 40 ns) has elapsed after the timing of raising of the first timer signal S11 high. When the first time Ta has elapsed after the timing of raising of the first timer signal S11 high, the first timer signal S11 is dropped low again. Hence, before time t1, the first timer signal S11 is a pulse signal which has a pulse width of the first time Ta.

Before time t1, the second timer circuit 458 receives an input of the first timer signal S11 which has a pulse width of the first time Ta to switch the second timer signal S13 low. In other words, before time t1, in the second timer circuit 458, the duration of the high level of the first timer signal S11 is the first time Ta, the duration does not reach the second time Tb (in the figure, 200 ns) and thus the second timer signal S13 is kept low.

Before time t1, in the RS flip-flop 461, the low-level second timer signal S13 is input to the set input end(S). Hence, the RS flip-flop 461 keeps the detection signal S8 low regardless of the logic level of the control signal S14 input to the reset input end (R) until time t1 arrives. The inverted signal S15 is kept high (not shown).

Before time t1, in the AND gate AG1, the control signal S9 kept high is input to the first input end, and the inverted signal S15 kept high is input to the second input end. Hence, the AND gate AG1 keeps the first drive control signal S4 high.

Before time t1, the inverter IVI receives an input of the control signal S9 kept high to keep the control signal S17 low (not shown). Hence, in the AND gate AG2, the control signal S17 kept low is input to the first input end, and the detection signal S8 kept low is input to the second input end. In this way, before time t1, the AND gate AG2 keeps the second drive control signal S5a low.

Before time t1, in the AND gate AG3, the control signal S9 kept high is input to the first input end, and the detection signal S8 kept low is input to the second input end. Hence, the AND gate AG3 keeps the second drive control signal S5b low before time t1.

As described above, before time t1, the first drive control signal S4 is kept high, and the second drive control signals S5a and S5b are kept low. Then, until time t1 arrives, the transistor P1 is turned on, the transistor N1 is turned off and the switches SW3a and Sw3b are turned off. In other words, the power supply voltage VCC2 is supplied from the third external terminal T3. Hence, before time t1, the voltage value of the drive voltage Vgh is kept high. Therefore, as described above, the period before time t1 is the on period Ton of the drive target switch SW1.

Before time t1, the third timer circuit 459 receives an input of the high-level inverted signal S15 to keep the third timer signal S16 low.

When time t1 arrives, the ECU 2 drops the input signal INH low while keeping the discharge signal ACD low. Then, the ECU 2 keeps the logic levels of the discharge signal ACD and the input signal INH until time t2 arrives.

During the period from time t1 to time t2, the logic circuit 416 receives inputs of the low-level input signal INH and the low-level discharge signal ACD. Hence, the logic circuit 416 keeps the first internal signal S1 low, and pulse-drives the second internal signal S2 at the normal period.

During the period from time t1 to time t2, in the RS flip-flop 456, the first internal signal S1 kept low is input to the set terminal(S), and the second internal signal S2 pulse-driven at the normal period is input to the reset terminal (R). Hence, the RS flip-flop 456 uses, as a trigger, the pulse edge (rising edge) generated in the second internal signal S2 at time t1 to drop the control signal S9 low (=to reset the control signal S9). Then, the RS flip-flop 456 keeps the control signal S9 low after time t1 until the subsequent pulse edge of the first internal signal S1 is detected (=until the on period of the drive target switch SW1 arrives) (not shown).

During the period from time t1 to time t2, in the OR gate OG1, the first internal signal S1 kept low is input to the first input end, and the second internal signal S2 pulse-driven at the normal period is input to the second input end. Hence, during the period from time t1 to time t2, the OR gate OG1 pulse-drives the monitoring signal S10 in synchronization with the pulse-driving of the second internal signal S2 (not shown).

During the period from time t1 to time t2, the first timer circuit 457 raises the first timer signal S11 from a low level to a high level in accordance with the timing of the pulse of the monitoring signal S10 (=timing of the pulse of the second internal signal S2). Then, the first timer signal S11 is kept high until the first time Ta (in the figure, 40 ns) has elapsed after the timing of raising of the first timer signal S11 high. When the first time Ta has elapsed after the timing of raising of the first timer signal S11 high, the first timer signal S11 is dropped low again. Hence, during the period from time t1 to time t2, the first timer signal S11 is a pulse signal which has a pulse width of the first time Ta.

During the period from time t1 to time t2, the second timer circuit 458 receives an input of the first timer signal S11 which has a pulse width of the first time Ta to switch the second timer signal S13 low. In other words, since the duration of the high level of the first timer signal S11 is the first time Ta but does not reach the second time Tb (in the figure, 200 ns), the second timer circuit 458 keeps the second timer signal S13 low.

During the period from time t1 to time t2, in the RS flip-flop 461, the low-level second timer signal S13 is input to the set input end(S). Hence, regardless of the logic level of the control signal S14 input to the reset input end (R), the RS flip-flop 461 keeps the detection signal S8 low. Therefore, here, the inverted signal S15 is kept high (not shown).

During the period from time t1 to time t2, in the AND gate AG1, the control signal S9 kept low is input to the first input end, and the inverted signal S15 kept high is input to the second input end. Hence, the AND gate AG1 keeps the first drive control signal S4 low (not shown).

During the period from time t1 to time t2, the inverter IVI receives an input of the control signal S9 kept low to keep the control signal S17 high (not shown). Hence, in the AND gate AG2, the control signal S17 kept high is input to the first input end, and the detection signal S8 kept low is input to the second input end. In this way, the AND gate AG2 keeps the second drive control signal S5a low until time t2 arrives (not shown).

During the period from time t1 to time t2, in the AND gate AG3, the control signal S9 kept low is input to the first input end, and the detection signal S8 kept low is input to the second input end. Hence, the AND gate AG3 keeps the second drive control signal S5b low (not shown).

As described above, during the period from time t1 to time t2, the first drive control signal S4 and the second drive control signals S5a and S5b are kept low. Then, until time t2 arrives, the transistor P1 is turned off, the transistor N1 is turned on and the switches SW3a and SW3b are turned off. Hence, the reference voltage VEE2 is supplied from the fourth external terminal T4. Therefore, during the period from time t1 to time t2, the drive voltage Vgh is kept low. Consequently, as described above, the period from time t1 to time t2 is the off-period Toff of the drive target switch SW1.

During the period from time t1 to time t2, the third timer circuit 459 receives an input of the high-level inverted signal S15 to keep the third timer signal S16 low.

When time t2 arrives, the ECU 2 raises the discharge signal ACD high while keeping the input signal INH low. Then, at time t3 when a predetermined time has elapsed since time t2, the ECU 2 raises the input signal INH high while keeping the discharge signal ACD low. Then, during the soft turn-on period Tson, that is, a period until time t6 arrives, the ECU 2 keeps the logic levels of the discharge signal ACD and the input signal INH.

During a period from time t3 to time t4a, that is, a period after time t3 until the pulse stop time Td has elapsed, the logic circuit 416 receives inputs of the low-level input signal INH and the high-level discharge signal ACD to keep the first internal signal S1 low and to pulse-drive the second internal signal S2 at the specific period. When time t4a arrives, the logic circuit 416 keeps the second internal signal S2 low while keeping the first internal signal S1 low.

During the period from time t3 to time t4a, in the RS flip-flop 456, the first internal signal S1 kept low is input to the set terminal(S), and the second internal signal S2 pulse-driven at the specific period is input to the reset terminal (R). At time t3, the output end (Q) of the RS flip-flop 456 (=the logic level of the control signal S9) is set low. Hence, as described above, during a period until time t7 when the first internal signal S1 input to the set terminal(S) is subsequently pulse-driven, the RS flip-flop 456 keeps the control signal S9 low.

During the period from time t3 to time t4a, in the OR gate OG1, the first internal signal S1 kept low is input to the first input end, and the second internal signal S2 pulse-driven at the specific period is input to the second input end. Hence, during the period from time t3 to time t4a, the OR gate OG1 pulse-drives the monitoring signal S10 in synchronization with the pulse-driving of the second internal signal S2 (not shown).

When time t3 arrives, the first timer circuit 457 raises the first timer signal S11 high in accordance with the timing of the pulse of the monitoring signal S10 (=timing of the pulse of the second internal signal S2). During the period from time t3 to time t4a, the second internal signal S2 is pulse-driven at the specific period shorter than the first time Ta. Hence, before the first time Ta has elapsed after the timing of the pulse of the monitoring signal S10, the subsequent timing of the pulse of the monitoring signal S10 arrives. In this way, the first timer circuit 457 keeps the first timer signal S11 high without dropping the first timer signal S11 low.

When time t4 arrives after the second time Tb has elapsed since the time t3, the second timer circuit 458 determines that the duration of the high level of the first timer signal S11 reaches the second time Tb to raise the second timer signal S13 high. In other words, during a period until time t4 arrives, the second timer circuit 458 keeps the second timer signal S13 low.

During a period from time t3 to time t4, in the RS flip-flop 461, the low-level second timer signal S13 is input to the set input end(S). In the meantime, the low-level third timer signal S16 is input to the reset input end (R). Hence, during the period from time t3 to time t4, the RS flip-flop 461 keeps the detection signal S8 low.

During the period from time t3 to time t4, in the AND gate AG1, the low-level control signal S9 is input to the first input end, and the low-level detection signal S8 is input to the second input end. Hence, during the period from time t3 to time t4, the AND gate AG1 keeps the first drive control signal S4 low.

During the period from time t3 to time t4, in the AND gate AG2, the high-level control signal S17 is input to the first input end, and the low-level detection signal S8 is input to the second input end. Hence, during the period from time t3 to time t4, the AND gate AG2 keeps the second drive control signal S5a low.

During the period from time t3 to time t4, in the AND gate AG3, the low-level control signal S9 is input to the first input end, and the low-level detection signal S8 is input to the second input end. Hence, during the period from time t3 to time t4, the AND gate AG3 keeps the second drive control signal S5b low.

Hence, during the period from time t3 to time t4, the transistor P1 is turned off, the transistor N1 is turned on and the switches SW3a and SW3b are turned off. Hence, the reference voltage VEE2 is supplied from the fourth external terminal T4. Therefore, the drive voltage Vgh is kept low.

At time t4 when the pulse stop time Td has elapsed since time t3, the logic circuit 416 (more specifically, the pulse generation circuit 453) stops the pulse of the second internal signal S2 to keep the second internal signal S2 low. Then, the first timer circuit 457 drops the first timer signal S11 low at time t4b when the first time Ta has elapsed since time t4a. Hence, at time t4b, the second timer circuit 458 drops the second timer signal S13 low.

When the second timer signal S13 is raised high at time t4, the RS flip-flop 461 raises the detection signal S8 high. Here, the RS flip-flop 461 drops the inverted signal S15 low. When the second timer signal S13 is dropped low at time t4b, the low-level control signal S14 is input to the reset input end (R) of the RS flip-flop 461. Hence, at time t4b, the RS flip-flop 461 holds the detection signal S8 high and holds the inverted signal S15 low.

When the inverted signal S15 is dropped low at time t4, the third timer circuit 459 receives an input of the low-level inverted signal S15 to raise the third timer signal S16 high. When time t5 arrives after the third time Tc has elapsed since time t4, the third timer circuit 459 drops the third timer signal S16 low.

During a period from time t4 to time t5, in the NOR gate NG1, the high-level third timer signal S16 is input to the second input end. Hence, during the period from time t4 to time t5, the NOR gate NG1 keeps the control signal S14 low regardless of the logic level of the monitoring signal S10 input to the first input end thereof. Therefore, even after time t4b, the RS flip-flop 461 holds the detection signal S8 high while the control signal S14 is being kept low.

During a period from time t4 to time t7, in the AND gate AG2, the high-level control signal S17 is input to the first input end, and the high-level detection signal S8 is input to the second input end. Hence, during the period from time t4 to time t7, the AND gate AG2 keeps the second drive control signal S5a high.

During the period from time t4 to time t7, in the AND gate AG3, the control signal S9 kept low is input to the first input end, and the detection signal S8 kept high is input to the second input end. Hence, during the period from time t4 to time t7, the AND gate AG3 keeps the second drive control signal S5b low.

During the period from time t4 to time t7, the driver circuit 501 receives an input of the high-level second drive control signal S5a to switch the transistors P1 and N1 off regardless of the logic level of the first drive control signal S4. Hence, during the period from time t4 to time t7, the third external terminal T3 and the fourth external terminal T4 are brought into a high impedance state.

During the period from time t4 to time t7, an input of the high-level second drive control signal S5a is received, and thus the switch SW3b is turned on. In this way, the soft turn-on signal Son is supplied from the sixth external terminal T6. Hence, during the period from time t4 to time t7, the drive voltage Vgh corresponds to the soft turn-on signal Son. In other words, during the period from time t4 to time t7, the drive voltage Vgh is gradually increased with a predetermined slew rate (=corresponding to the soft turn-on signal Son). Therefore, the period from time t4 to time t7 is the soft turn-on period Tson of the drive target switch SW1.

When time t6 arrives after a predetermined time has elapsed since time t5, the ECU 2 drops the discharge signal ACD low. Thereafter, when time t7 arrives, the ECU 2 drops the input signal INH low while keeping the discharge signal ACD low. Then, after time t7, the ECU 2 keeps the input signal INH low until the subsequent on period Ton of the drive target switch SW1 arrives.

When the input signal INH is dropped low at time t7, the logic circuit 416 receives inputs of the low-level input signal INH and the low-level discharge signal ACD to pulse-drive the second internal signal S2 at the normal period while keeping the first internal signal S1 low. In other words, the state of the first internal signal S1 and the second internal signal S2 is the same as the state during the period from time t1 to time 12.

Hence, after time t7, the signals are controlled in the same manner as during the period from time t1 to time t2. A specific description will be given below.

As described above, after time t7, the control signal S9 is kept low, and the monitoring signal S10 is pulse-driven in synchronization with the pulse-driving of the second internal signal S2. The first timer signal S11 is pulse-driven to have a pulse width of the first time Ta. The second timer signal S13 is kept low, the detection signal S8 is kept low and the inverted signal S15 is kept high. In this way, the first drive control signal S4 and the second drive control signals S5a and S5b are kept low.

Hence, after time t7, the drive voltage Vgh is dropped low as during the period from time t1 to time t2, and the period after time t7 is the off-period Toff of the drive target switch SW1.

During the soft turning off, the edge detection circuit 450 detects the rising edge of the input signal INH to raise the control signal S7 low. In this case, the first internal signal S1 is pulse-driven at the specific period, and the second internal signal S2 is kept low. The internal control here is basically the same as the internal control during the soft turning on described above, and they differ in the following respect.

When the soft turn-on control described above is replaced with the soft turn-off control, during the period from time t3 to time t4a, the first internal signal S1 pulse-driven at the specific period is input to the first input end, and the second internal signal S2 kept low is input to the second input end. Hence, during the period from time t3 to time t4a, the OR gate OG1 pulse-drives the monitoring signal S10 in synchronization with the pulse-driving of the first internal signal S1.

<about DESAT Protection Circuit>

Incidentally, the electronic device 400 has a DESAT protection function for the drive target switch SW1. A configuration related to the DESAT protection function for the drive target switch SW1 will be described below. With reference back to FIG. 11, the electronic device 400 includes, in addition to the discrete components described above, the resistor R3, a diode d5 and the capacitor C3.

The first end of the resistor R3 is connected to the external terminal (more specifically, an eighth external terminal T8 which will be described later) of the signal transmission device 200X. The second end of the resistor R3 is connected to the anode of the diode d5. The cathode of the diode d5 is connected to the node n1.

The first end of the capacitor C3 is connected to the first end of the resistor R3. The second end of the capacitor C3 is connected to the node n2, the first end of the capacitor C4 and the application end of the power supply voltage VCC2. The second end of the capacitor C4 is connected to the application end of the reference voltage VEE2. A low-pass filter is configured by the third external terminal T3, the capacitor C3 and the diode d5. The second end of the capacitor C4 is connected to the application end of the reference voltage VEE2.

The signal transmission device 200X includes, in addition to the configuration described above, a seventh external terminal T7 and an eighth external terminal T8. The seventh external terminal T7 and the eighth external terminal T8 are terminals for establishing electrical connection to the outside. The seventh external terminal T7 is provided in the controller chip 410. The eighth external terminal T8 is provided in the driver chip 420.

The controller chip 410 includes, in addition to the configuration described above, a third reception circuit 413 and a fourth transmission circuit 414.

The third reception circuit 413 is connected to the seventh external terminal T7. The third reception circuit 413 receives an input of an SAT monitoring signal Sdst from a third transmission circuit 423 which will be described later via the transformer chip 430 (more specifically, the third transformer 433). The third reception circuit 413 inputs the input SAT monitoring signal Sdst to the ECU 2 via the seventh external terminal T7.

The fourth transmission circuit 414 is connected to the first external terminal T1. The fourth transmission circuit 414 receives an input of the input signal INH form the ECU 2 via the first external terminal T1. The fourth transmission circuit 414 transmits the input signal INH which has been input to the driver chip 420 (more specifically, a fourth reception circuit 424 which will be described later) via the transformer chip 430 (more specifically, the fourth transformer 434).

The driver chip 420 includes, in addition to the configuration described above, the third transmission circuit 423, the fourth reception circuit 424 and a DESAT protection circuit 440.

The third transmission circuit 423 is connected to the DESAT protection circuit 440. The third transmission circuit 423 receives an input of the SAT monitoring signal Sdst from the DESAT protection circuit 440. The third transmission circuit 423 inputs the input SAT monitoring signal Sdst to the third reception circuit 413 via the transformer chip 430 (more specifically, the third transformer 433).

The fourth reception circuit 424 is connected to the DESAT protection circuit 440. The fourth reception circuit 424 receives an input of the input signal INH from the fourth transmission circuit 414 via the transformer chip 430 (more specifically, the fourth transformer 434). The fourth reception circuit 424 inputs the input signal INH which has been input to the DESAT protection circuit 440.

The DESAT protection circuit 440 is connected to the third transmission circuit 423, the fourth reception circuit 424 and the eighth external terminal T8. The DESAT protection circuit 440 receives an input of the input signal INH as described above. The DESAT protection circuit 440 inputs the SAT monitoring signal Sdst to the third transmission circuit 423 as described above.

The DESAT protection circuit 440 is a circuit which monitors an SAT (saturation) voltage for the drive target switch SW1 to protect the drive target switch SW1 from an overcurrent and an overvoltage. The SAT voltage refers to a voltage between the base and the emitter during the on period of the drive target switch SW1.

The DESAT protection circuit 440 causes a predetermined monitoring current Im to flow between the collector and the emitter during the on period of the drive target switch SW1. Here, a voltage is generated across the resistor R3. The DESAT protection circuit 440 detects the voltage generated across the resistor R3 via the eighth external terminal T8 to monitor the SAT voltage for the drive target switch SW1.

The DESAT protection circuit 440 determines, based on the logic level of the input signal INH, the on period and the off period of the drive target switch SW1. Specifically, when the input signal INH is high, the DESAT protection circuit 440 determines that the drive target switch SW1 is in the on period to output the monitoring current Im. By contrast, when the input signal INH is low, the DESAT protection circuit 440 determines that the drive target switch SW1 is in the off period to stop the output of the monitoring current Im.

The DESAT protection circuit 440 generates the SAT monitoring signal Sdst corresponding to the monitored state. As described above, the SAT monitoring signal Sdst is input to the ECU 2 via the third transmission circuit 423, the third transformer 433 and the third reception circuit 413.

The ECU 2 controls the input signal INH and the discharge signal ACD according to the SAT monitoring signal Sdst. Specifically, when a voltage between the collector and the emitter exceeds a predetermined voltage value, the ECU 2 generates the input signal INH and the discharge signal ACD to turn off the drive target switch SW1. A specific description will be given below.

When the voltage between the collector and the emitter does not exceed the predetermined voltage value, the DESAT protection circuit 440 keeps the SAT monitoring signal Sdst low. When the voltage between the collector and the emitter exceeds the predetermined voltage value, the DESAT protection circuit 440 raises the SAT monitoring signal Sdst high.

When the SAT monitoring signal Sdst is low, the ECU 2 generates the input signal INH and the discharge signal ACD such that the drive target switch SW1 normally performs the on/off operation, the soft turn-on operation or the soft turn-off operation as described above. On the other hand, when the SAT monitoring signal Sdst is high, the ECU 2 drops the input signal INH and the discharge signal ACD low such that the drive target switch SW1 is forcibly brought into an off state.

Hence, when the SAT monitoring signal Sdst is high, the first internal signal S1 and the second internal signal S2 kept low are input to the logic circuit 429. In this way, the first drive circuit 426 is enabled, and the soft turn-on control circuit 502a and the soft turn-off control circuit 502b are disabled. Here, the drive signal GH is switched high to be the drive signal GL. Hence, when the SAT monitoring signal Sdst is switched high, the drive target switch SW1 is turned off.

As described above, when the voltage between the collector and the emitter exceeds the predetermined voltage value during the on period of the drive target switch SW1, the drive target switch SW1 is turned off. Hence, the drive target switch SW1 is protected from an overvoltage and an overcurrent.

### <About DESAT Protection Standby Time>

As described above, the DESAT protection circuit 440 outputs the monitoring current Im during the on period of the drive target switch SW1. On the other hand, during the off period of the drive target switch SW1, an area between the collector and the emitter of the drive target switch SW1 is in a non-conductive state. Hence, as described above, the DESAT protection circuit 440 stops the output of the monitoring current Im.

Here, at a timing when the input signal INH is raised from a low level to a high level, the drive voltage Vgh is raised from a low level to a high level. More precisely, at this timing, the drive voltage Vgh transitions steeply from a low level to a high level with a slight slew rate. Hence, strictly speaking, the drive target switch SW1 transitions from an off state to an on state over a predetermined transition time after the timing at which the input signal INH is raised high.

It is assumed that when the input signal INH is raised high, the DESAT protection circuit 440 is started. In this case, in the middle of transition of the drive target switch SW1 from an off state to an on state, the DESAT protection circuit 440 starts the output of the monitoring current Im.

When at this point, the drive voltage Vgh does not exceed the on-threshold voltage of the drive target switch SW1, the area between the collector and the emitter of the drive target switch SW1 is in a non-conductive state. When in this state, the drive target switch SW1 outputs the monitoring current Im, no current flows through the drive target switch SW1, and thus the capacitor C3 is unintentionally charged.

Then, a voltage at the eighth external terminal T8 is increased regardless of the SAT voltage for the drive target switch SW1. Hence, although the drive target switch SW1 is not in an overvoltage state, the DESAT protection circuit 440 makes erroneous detection.

In order to prevent the occurrence of the erroneous detection described above, in the DESAT protection circuit 440 in the present disclosure, a predetermined blanking period is provided after the input signal INH is raised high. The blanking period is a period during which the drive target switch SW1 is not turned on and the DESAT protection circuit 440 is on standby.

The blanking period is set based on a general time during which the transition of the drive voltage Vgh from a low level to a high level is completed. For example, the blanking period is set to 50 ns to 600 ns.

### <Considerations on Blanking Period>

Incidentally, the signal transmission device 200X in the present disclosure may soft turn on the drive target switch SW1 as described above. In this case, since the drive target switch SW1 is in the on period, the DESAT protection circuit 440 monitors the SAT voltage for the drive target switch SW1. However, as described above, the soft turn-on signal Son is gradually increased with a relatively gentle slew rate. At a timing when the off period of the drive target switch SW1 is switched to the soft turn-on period, as compared with a normal timing at which an off period is switched to an on period, the time during which the transition of the drive voltage Vgh from a low level to a high level is completed is increased.

Then, even if the blanking period as described above is set, when the blanking period has elapsed, it is likely that the drive voltage Vgh does not exceed the on-threshold voltage of the drive target switch SW1. Then, in the off state of the drive target switch SW1, the DESAT protection circuit 440 starts the output of the monitoring current Im. Hence, as described above, the DESAT protection circuit 440 may make erroneous detection.

When the DESAT protection circuit 440 makes erroneous detection, in the middle of the soft turn-on operation of the drive target switch SW1, the ECU 2 forcibly drops the input signal INH and the discharge signal ACD low. Hence, the drive target switch SW1 is turned off, and thus active discharge cannot be performed effectively, with the result that it is impossible to suitably draw out charge from the capacitor C1.

Hence, the signal transmission device 200X in the present disclosure is configured to be able to suppress erroneous detection made by the DESAT protection circuit 440. A specific description will be given below.

The controller chip 410 includes a fifth transmission circuit 415 in addition to the configuration described above. The fifth transmission circuit 415 is connected to the second external terminal T2. The fifth transmission circuit 415 receives an input of the discharge signal ACD from the ECU 2 via the second external terminal T2. The fifth transmission circuit 415 inputs the input discharge signal ACD to the driver chip 420 (more specifically, a fifth reception circuit 425 which will be described later) via the transformer chip 430 (more specifically, the fifth transformer 435 which will be described later).

The driver chip 420 includes the fifth reception circuit 425 in addition to the configuration described above. The fifth reception circuit 425 receives an input of the discharge signal ACD from the fifth transmission circuit 415 via the transformer chip 430 (more specifically, the fifth transformer 435 which will be described above). The fifth transmission circuit 415 inputs the discharge signal ACD to the DESAT protection circuit 440.

As described above, the DESAT protection circuit 440 receives an input of the discharge signal ACD from the fifth reception circuit 425. The DESAT protection circuit 440 determines, based on the input signal INH and the discharge signal ACD which have been input, whether the drive target switch SW1 is in the soft turn-on period. A specific description will be given below.

When the input signal INH is high, and the discharge signal ACD is low, the DESAT protection circuit 440 determines that the drive target switch SW1 is in a normal on period. Here, the DESAT protection circuit 440 is in a standby state during a first blanking period TB1 after the input signal INH is raised high without outputting the monitoring current Im. Then, the DESAT protection circuit 440 outputs the monitoring current Im after the first blanking period TB1 has elapsed.

When the input signal INH is high, and the discharge signal ACD is low, the DESAT protection circuit 440 determines that the drive target switch SW1 is in the soft turn-on period. Here, the DESAT protection circuit 440 is in the standby state during a second blanking period TB2 after the input signal INH is raised high without outputting the monitoring current Im. Then, the DESAT protection circuit 440 outputs the monitoring current Im after the second blanking period TB2 has elapsed.

When the input signal INH is low, as described above, the DESAT protection circuit 440 determines that the drive target switch SW1 is in an off state to enter the standby state without outputting the monitoring current Im.

The second blanking period TB2 is set longer than the first blanking period TB1. The second blanking period TB2 is set equal to or greater than 1.5 times and equal to or less than 160 times the first blanking period TB1. For example, when the first blanking period TB1 is set to 1 ns to 600 ns, the second blanking period TB2 is preferably set to 1 us to 8 μs. The second blanking period TB2 is preferably equal to or greater than 10 times and equal to or less than 30 times the first blanking period TB1. A specific description will be given below.

FIG. 14 is a table showing the set state of the first blanking period TB1 and the second blanking period TB2. For example, as shown in FIG. 14, it is assumed that the first blanking period TB1 is so set to No. 1 as to be 200 ns. It is also assumed that the second blanking period TB2 is set to 3 μs.

In this case, it is assumed that the DESAT protection circuit 440 determines that the drive target switch SW1 is in an on period. Then, the DESAT protection circuit 440 is in the standby state for 200 ns after the input signal INH is raised high.

In this case, it is assumed that the DESAT protection circuit 440 determines that the drive target switch SW1 is in the soft turn-on period. Then, the DESAT protection circuit 440 is in the standby state for 3 us after the input signal INH is raised high.

As described above, when the drive target switch SW1 is in the soft turn-on period, the DESAT protection circuit 440 in the present disclosure is in the standby state during the second blanking period TB2 which is relatively a long time after the input signal INH is raised high. Hence, as described above, the output of the monitoring current Im performed by the DESAT protection circuit 440 in a state where the drive voltage Vgh does not exceed the on-threshold voltage of the drive target switch SW1 is suppressed.

In this way, it is possible to suppress erroneous detection made by the DESAT protection circuit 440 when the drive target switch SW1 is in the soft turn-on period.

### <Variation>

The present disclosure is not limited to the embodiment described above, and various changes can be made without departing from the spirit of the present disclosure. For example, although the drive target switch SW1 is an IGBT, the present disclosure is not limited to this configuration. For example, the drive target switch SW1 can be an N-channel or P-channel MOSFET. In this case, the emitter and the collector of the drive target switch SW1 are replaced with the source and the drain, and thus the meanings of the present specification, FIG. 1 to FIG. 16 and the scope of claims can be interpreted. The SAT voltage here is interpreted to be a voltage between the gate and source during the on period of the drive target switch SW1.

### Example of Implementation of Signal Transmission Device 200X in the Present Disclosure

FIG. 15 is a block diagram showing an example of implementation of the signal transmission device 200X in the present disclosure. FIG. 16 is a diagram showing the vehicle A which includes the electronic device 400. The electronic device 400 which incorporates the signal transmission device 200X in the present disclosure can be suitably utilized in the vehicle A (see FIG. 16) which is an engine vehicle or an electric vehicle. The electronic device 400 can be utilized as a motor driving device which performs drive control on the motor M incorporated in the vehicle A.

As shown in FIG. 15, the motor M is a three-phase motor which is driven to rotate according to three-phase drive voltages U/V/W which are respectively input from three-phase (U-phase/V-phase/W-phase) half-bridge output stages.

The electronic device 400 includes three insulated gate drivers 1H (u/v/w), three insulated gate drivers 1L (u/v/w), three high-side switch elements SWH (u/v/w), three low-side switch elements SWL (u/v/w), the ECU 2 and the capacitor C1.

The insulated gate drivers 1H (u/v/w) respectively drive the high-side switch elements SWH (u/v/w) by generating, while insulating areas between the ECU 2 and the high-side switch elements SWH (u/v/w), an upper gate drive signal (corresponding to the drive voltage Vgh described above) according to an upper gate control signal INH (corresponding to the input signal INH described above) input from the ECU 2.

The insulated gate drivers 1L (u/v/w) respectively drive the low-side switch elements SWL (u/v/w) by generating, while insulating areas between the ECU 2 and the low-side switch elements SWL (u/v/w), a lower gate drive signal (corresponding to the drive voltage Vgh described above) according to a lower gate control signal INL (corresponding to the input signal INH described above) input from the ECU 2.

The high-side switch elements SWH (u/v/w) are gate-driven by the insulated gate drivers 1H (u/v/w), respectively. The high-side switch elements SWH (u/v/w) are respectively connected to areas between a power system power supply end (=application end of the first motor drive voltage VD1) and the input ends of the phases of the motor M.

The low-side switch elements SWL (u/v/w) are gate-driven by the insulated gate drivers 1L (u/v/w), respectively. The low-side switch elements SWL (u/v/w) are respectively connected to areas between the input ends of the phases of the motor M and a power system ground end (=application end of the second motor drive voltage VD2).

Although in the figure, the IGBTs are used as the high-side switch elements SWH (u/v/w) and the low-side switch elements SWL (u/v/w), as described above, SiC-MOSFETs or Si-MOSFETs can be used instead of the IGBTs.

The ECU 2 drives the high-side switch elements SWH (u/v/w) and the low-side switch elements SWL (u/v/w) via the insulated gate drivers 1H (u/v/w) and 1L (u/v/w), respectively, and thereby controls the rotational drive of the motor M. The ECU 2 also has the function of performing various types of safety control by monitoring the FLT1 terminals and FLT2 terminals of the insulated gate drivers 1H (u/v/w) and 1L (u/v/w).

A capacitor C1 (corresponding to the capacitor C1 described above) is provided which smoothes a voltage between the application ends of the first motor drive voltage VD1 and the second motor drive voltage VD2. The capacitor C1 stabilizes a direct-current voltage (=voltage between the application ends of the first motor drive voltage VD1 and the second motor drive voltage VD2) which changes according to a change in the power consumption of the motor M.

Here, the signal transmission device 200X described above can be suitably used as the insulated gate drivers 1H (u/v/w) and 1L (u/v/w). For example, one phase (in the figure, for example, the U-phase) of the three phases can be used as the signal transmission device 200X.

When the signal transmission device 200X is used as the insulated gate drivers 1H (u/v/w), the switching element SW1 shown in FIG. 10 serves as the high-side switch elements SWH (u/v/w) shown in FIG. 15. In this case, the node n1 shown in FIG. 10 and FIG. 11 is said to be the application end of the first motor drive voltage VD1. The node n2 shown in FIG. 10 and FIG. 12 is said to be the connection end of the motor M shown in FIG. 15.

When the signal transmission device 200X is used as the insulated gate drivers 1L (u/v/w), the switching element SW1 shown in FIG. 11 serves as the low-side switch elements SWL (u/v/w) shown in FIG. 15. In this case, the node n1 shown in FIG. 11 is said to be the connection end of the motor M shown in FIG. 15. The node n2 shown in FIG. 11 is said to be the application end of the second motor drive voltage VD2 shown in FIG. 15. In this case, the input signal INH in FIG. 11 and in the description corresponding to FIG. 11 can be interpreted by being replaced with the input signal INL.

### <Additional Notes>

A signal transmission device (200X) disclosed in the specification includes: a transmission-side circuit (410) configured to output a first internal signal (S1) and a second internal signal (S2) that are pulse-driven according to a first input signal (INH, INL); a reception-side circuit (420) configured to output a drive voltage (Vgh) according to the first internal signal (S1) and the second internal signal (S2) so as to drive and control a drive target switch (SW1); an insulating circuit (430) configured to transmit the first internal signal (S1) and the second internal signal (S2) while insulating an area between the transmission-side circuit (410) and the reception-side circuit (420); and a protection circuit (440) configured to monitor an SAT voltage for the drive target switch (SW1) during an on period (Ton, Tson) of the drive target switch (SW1), the transmission-side circuit (410) drives at least one of the first internal signal (S1) and the second internal signal (S2) according to a second input signal (ACD) different from the first input signal (INH, INL) at a specific period different from a period of the first input signal (INH, INL), the reception-side circuit (420) includes: a first drive circuit (426) configured to generate the drive voltage (Vgh) based on the first input signal (INH, INL) in a state where the reception-side circuit (420) is enabled so as to drive and control the drive target switch (SW1); a second drive circuit (502) configured to generate, in the state where the reception-side circuit (420) is enabled, the drive voltage (Vgh) to drive the drive target switch (SW1) at a speed lower than a speed of the first drive circuit (426) so as to drive and control the drive target switch (SW1); and a drive control circuit (429) configured to detect that a period of at least one of the first internal signal (S1) and the second internal signal (S2) is the specific period so as to disable the first drive circuit (426) and enable the second drive circuit (502), when the first drive circuit (426) is enabled and the second drive circuit (502) is disabled, based on the first input signal (INH, INL) and the second input signal (ACD), the protection circuit (440) starts monitoring the SAT voltage after a first blanking period (TB1) has elapsed since a starting point of a transition period from an off state to an on state of the drive target switch (SW1) or a transition period from the on state to the off state and when the first drive circuit (426) is disabled and the second drive circuit (502) is disabled, based on the first input signal (INH, INL) and the second input signal (ACD), the protection circuit (440) starts monitoring the SAT voltage after a second blanking period (TB2) longer than the first blanking period (TB1) has elapsed since the starting point (first configuration).

In the signal transmission device (200X) according to the first configuration, the second blanking period (TB2) is equal to or greater than 1.5 times and equal to or less than 160 times the first blanking period (TB1) (second configuration).

In the signal transmission device (200X) according to the first or second configuration, the second drive circuit (502) includes: a soft turn-on control circuit (502a) configured to generate, in a state where the second drive circuit (502) is enabled, a soft turn-on signal (Son) as the drive voltage (Vgh) that drives and controls the drive target switch (SW1) to turn the drive target switch (SW1) from the off state to the on state during a predetermined transition period so as to drive and control the drive target switch (SW1); and a soft turn-off control circuit (502b) configured to generate, in the state where the second drive circuit (502) is enabled, a soft turn-off signal (Soff) as the drive voltage (Vgh) that drives and controls the drive target switch (SW1) to turn the drive target switch (SW1) from the on state to the off state during the predetermined transition period so as to drive and control the drive target switch (SW1), and the state where the second drive circuit (502) is enabled is one of a state where the soft turn-on control circuit (502a) is enabled and the soft turn-off control circuit (502b) is disabled and a state where the soft turn-on control circuit (502a) is disabled and the soft turn-off control circuit (502b) is enabled (third configuration).

An electronic device (400) disclosed in the specification incudes: the signal transmission device (200X) according to any one of the first to third configurations; a control circuit (2) configured to generate the first input signal (INH, INL) and the second input signal (ACD); and the drive target switch (SW1) (fourth configuration).

In the electronic device (400) according to the fourth configuration, the protection circuit (440) generates a monitoring signal (Sdst) based on a result of the monitoring, and the control circuit (2) generates the first input signal (INH, INL) based on the monitoring signal (Sdst) (fifth configuration).

In the electronic device (400) according to the fifth configuration, the protection circuit (440) generates the monitoring signal (Sdst) corresponding to whether the SAT voltage exceeds a predetermined voltage value, and when the control circuit (2) determines, based on the monitoring signal (Sdst), that the SAT voltage exceeds the voltage value, the control circuit (2) generates the first input signal (INH, INL) and the second input signal (ACD) such that the drive target switch (SW1) is brought into the off state (sixth configuration).

A vehicle (A) disclosed in the specification includes: the electronic device (400) according to one of the fourth and fifth configurations (seventh configuration).

1. A signal transmission device comprising:
a transmission-side circuit configured to output a first internal signal and a second internal signal that are pulse-driven according to a first input signal;
a reception-side circuit configured to output a drive signal according to the first internal signal and the second internal signal so as to drive and control a drive target switch;
an insulating circuit configured to transmit the first internal signal and the second internal signal while insulating an area between the transmission-side circuit and the reception-side circuit; and
a protection circuit configured to monitor an SAT voltage for the drive target switch during an on period of the drive target switch,
wherein the transmission-side circuit drives at least one of the first internal signal and the second internal signal according to a second input signal different from the first input signal at a specific period different from a period of the first input signal,
the reception-side circuit includes:
a first drive circuit configured to generate the drive signal based on the first input signal in a state where the reception-side circuit is enabled so as to drive and control the drive target switch;
a second drive circuit configured to generate, in the state where the reception-side circuit is enabled, the drive signal to drive the drive target switch at a speed lower than a speed of the first drive circuit so as to drive and control the drive target switch; and
a drive control circuit configured to detect that a period of at least one of the first internal signal and the second internal signal is the specific period so as to disable the first drive circuit and enable the second drive circuit,
when the first drive circuit is enabled and the second drive circuit is disabled, based on the first input signal and the second input signal, the protection circuit starts monitoring the SAT voltage after a first blanking period has elapsed since a starting point of a transition period from an off state to an on state of the drive target switch or a transition period from the on state to the off state and
when the first drive circuit is disabled and the second drive circuit is disabled, based on the first input signal and the second input signal, the protection circuit starts monitoring the SAT voltage after a second blanking period longer than the first blanking period has elapsed since the starting point.

2. The signal transmission device according to claim 1,
wherein the second blanking period is equal to or greater than 1.5 times and equal to or less than 160 times the first blanking period.

3. The signal transmission device according to claim 1,
wherein the second drive circuit includes:
a soft turn-on control circuit configured to generate, in a state where the second drive circuit is enabled, a soft turn-on signal as the drive signal that drives and controls the drive target switch to turn the drive target switch from the off state to the on state during a predetermined transition period so as to drive and control the drive target switch; and
a soft turn-off control circuit configured to generate, in the state where the second drive circuit is enabled, a soft turn-off signal as the drive signal that drives and controls the drive target switch to turn the drive target switch from the on state to the off state during the predetermined transition period so as to drive and control the drive target switch, and
the state where the second drive circuit is enabled is one of a state where the soft turn-on control circuit is enabled and the soft turn-off control circuit is disabled and a state where the soft turn-on control circuit is disabled and the soft turn-off control circuit is enabled.

4. An electronic device comprising:
the signal transmission device according to claim 1;
a control circuit configured to generate the first input signal and the second input signal; and
the drive target switch.

5. The electronic device according to claim 4,
wherein the protection circuit generates a monitoring signal based on a result of the monitoring of the SAT voltage, and
the control circuit generates the first input signal based on the monitoring signal.

6. The electronic device according to claim 5,
wherein the protection circuit generates the monitoring signal corresponding to whether the SAT voltage exceeds a predetermined voltage value, and
when the control circuit determines, based on the monitoring signal, that the SAT voltage exceeds the voltage value, the control circuit generates the first input signal and the second input signal such that the drive target switch is brought into the off state.

7. A vehicle comprising:
the electronic device according to claim 4.
